(19) United States
(12) Patent Application Publication
(10) Pub. No.: US 2025/0338502 A1
(43) Pub. Date: Oct. 30, 2025

(54) SEMICONDUCTOR MEMORY DEVICE

(71) Applicant: Samsung Electronics Co., Ltd., Suwon-si (KR)

(72) Inventors: Min Soo KIM, Suwon-si (KR); Seung Hoon KIM, Suwon-si (KR); Yong Kwan KIM, Suwon-si (KR); Hui Jung KIM, Suwon-si (KR); Su Min MOON, Suwon-si (KR); Tae Jin PARK, Suwon-si (KR); Ki Seok LEE, Suwon-si (KR); Hyeon Seok LEE, Suwon-si (KR); Hyun Jin LEE, Suwon-si (KR); Sung Soo YIM, Suwon-si (KR)

(21) Appl. No.: 18/949,149

(22) Filed: Nov. 15, 2024

(30) Foreign Application Priority Data
Apr. 29, 2024 (KR) 10-2024-0056982

(51) Int. Cl. H10B 51/40; G11C 5/06; H10B 51/10; H10B 53/10; H10B 53/40

(52) U.S. Cl. CPC H10B 51/40; G11C 5/063; H10B 51/10; H10B 53/10; H10B 53/40

(57) ABSTRACT

A semiconductor memory device including a peripheral circuit element disposed on a peripheral circuit substrate, a peripheral circuit contact structure connected to the peripheral circuit element, a first bonding pad disposed on the peripheral circuit contact structure, a second bonding pad disposed on the first bonding pad, an active pattern disposed on the second bonding pad, a data storage pattern disposed between the active pattern and the second bonding pad and connected to a first surface of the active pattern, a bit-line disposed on the active pattern, connected to a second surface of the active pattern, and extending in a second direction, a word-line disposed on a first sidewall of the active pattern, a back gate electrode disposed on a second sidewall of the active pattern, a first cell contact structure disposed between and connecting the second bonding pad and the data storage pattern.

### CROSS-REFERENCE TO RELATED APPLICATION

This application claims priority from Korean Patent Application No. 10-2024-0056982 filed on Apr. 29, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor memory device, and more specifically, to a semiconductor memory device including a vertical channel transistor (VCT).

### Description of Related Art

In order to meet high performance and low price of a semiconductor memory device as demanded by consumers, it is required to increase integration of the semiconductor memory device. The integration of the semiconductor memory device is an important factor in determining a price thereof. Thus, the semiconductor memory device particularly having increased integration is required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase thereof is limited. Accordingly, a semiconductor memory device including a vertical channel transistor in which a channel extends in a vertical direction is being proposed.

### SUMMARY

A technical purpose to be achieved by the present disclosure is to provide a semiconductor memory device with improved process yield.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

According to some aspects of the present disclosure, there is a semiconductor memory device comprising a peripheral circuit substrate, a peripheral circuit element disposed on the peripheral circuit substrate, a peripheral circuit contact structure disposed on the peripheral circuit substrate and connected to the peripheral circuit element, a first bonding pad disposed on the peripheral circuit contact structure, a second bonding pad disposed on the first bonding pad, an active pattern disposed on the second bonding pad and including a first surface and a second surface opposite to each other in a first direction, and a first sidewall and a second sidewall opposite to each other in a second direction, a data storage pattern disposed between the active pattern and the second bonding pad and connected to the first surface of the active pattern, a bit-line disposed on the active pattern, connected to the second surface of the active pattern, and extending in the second direction, a word-line disposed on the first sidewall of the active pattern and extending in a third direction, a back gate electrode disposed on the second sidewall of the active pattern and extending in the third direction, a first cell contact structure disposed between the second bonding pad and the data storage pattern so as to connect the second bonding pad and the data storage pattern to each other, a first lower contact via connecting the first cell contact structure and the back gate electrode to each other and a second lower contact via connecting the first cell contact structure and the word-line to each other, wherein a width of the first lower contact via decreases as the first lower contact via extends toward the back gate electrode, wherein a width of the second lower contact via decreases as the second lower contact via extends toward the word-line.

According to some aspects of the present disclosure, there is a semiconductor memory device comprising a peripheral circuit substrate, a peripheral circuit element disposed on the peripheral circuit substrate, a peripheral circuit contact structure disposed on the peripheral circuit substrate and connected to the peripheral circuit element, a first bonding pad disposed on the peripheral circuit contact structure, a second bonding pad disposed on the first bonding pad, a bit-line disposed on the second bonding pad, and including upper and lower surfaces opposite to each other in a first direction, wherein the bit-line extends in a second direction, a first word-line disposed on the upper surface of the bit-line and extending in a third direction, a second word-line disposed on the upper surface of the bit-line and extending in the third direction, the second word-line spaced apart from the first word-line in the second direction, a back gate electrode disposed on the upper surface of the bit-line and between the first word-line and the second word-line, the back gate electrode extending in the third direction, a first active pattern disposed between the first word-line and the back gate electrode and extending in the second direction, a second active pattern disposed between the second word-line and the back gate electrode and extending in the second direction, a data storage pattern disposed on the first and second active patterns and connected to the first active pattern and the second active pattern, a first cell contact structure disposed on the lower surface of the bit-line so as to connect the bit-line and the second bonding pad to each other, a first lower contact via connecting the first cell contact structure and the back gate electrode to each other; and a second lower contact via connecting the first cell contact structure and the first word-line to each other, wherein a width of the first lower contact via decreases as the first lower contact via extends toward the back gate electrode, wherein a width of the second lower contact via decreases as the second lower contact via extends toward the first word-line.

According to some aspects of the present disclosure, there is a semiconductor memory device comprising a peripheral circuit substrate, a peripheral circuit element disposed on the peripheral circuit substrate, a peripheral circuit contact structure disposed on the peripheral circuit substrate and connected to the peripheral circuit element, a first bonding pad disposed on the peripheral circuit contact structure, a second bonding pad disposed on the first bonding pad, an active pattern disposed on the second bonding pad and including a first surface and a second surface opposite to each other in a first direction, and a first sidewall and a second sidewall opposite to each other in a second direction, a data storage pattern disposed between the active pattern and the second bonding pad and connected to the first surface of the active pattern, a bit-line disposed on the active pattern, connected to the second surface of the active pattern, and extending in the second direction, a word-line disposed on the first sidewall of the active pattern and extending in a third direction, a back gate electrode disposed on the second sidewall of the active pattern and extending in the third direction, a first cell contact structure disposed between the second bonding pad and the data storage pattern so as to connect the second bonding pad and the data storage pattern to each other, a second cell contact structure disposed on the word-line or the back gate electrode, a first lower contact via connecting the first cell contact structure and the back gate electrode to each other, a first upper contact via connecting the second cell contact structure and the back gate electrode to each other, a second lower contact via connecting the first cell contact structure and the word-line to each other, a second upper contact via connecting the second cell contact structure and the word-line to each other, wherein each of a width of the first lower contact via and a width of the first upper contact via decreases as each of the first lower contact via and the first upper contact via extends toward the back gate electrode, and wherein each of a width of the second lower contact via and a width of the second upper contact via decreases as each of the second lower contact via and the second upper contact via extends toward the word-line.

### BRIEF DESCRIPTION OF DRAWINGS

The above and other aspects and features of the present disclosure will become more apparent by describing in detail embodiments thereof with reference to the attached drawings, in which:

FIG. 1 is a layout diagram of a semiconductor memory device according to some embodiments of the present disclosure.

FIG. 2 is a layout diagram of a boundary portion of a cell array area and a peripheral circuit area in FIG. 1.

FIG. 3 is a cross-sectional view cut along lines A-A and B-B of FIG. 2.

FIG. 4 is an enlarged view of a P1 portion of FIG. 3.

FIG. 5 is an enlarged view of a Q1 portion of FIG. 3.

FIG. 6 and FIG. 7 are enlarged views of a Q2 portion of FIG. 3.

FIG. 8 is a layout diagram of a boundary portion of the cell array area and the peripheral circuit area in FIG. 1.

FIG. 9 is a cross-sectional view cut along C-C and D-D in FIG. 8.

FIG. 10 is an enlarged view of a P2 portion of FIG. 9.

FIG. 11 is an enlarged view of a Q3 portion of FIG. 9.

FIG. 12 and FIG. 13 are enlarged views of a Q4 portion of FIG. 9.

FIGS. 14 to 17 are diagrams for illustrating a semiconductor memory device manufacturing method according to some embodiments of the present disclosure.

FIGS. 18 to 21 are diagrams for illustrating a semiconductor memory device manufacturing method according to some embodiments of the present disclosure.

FIGS. 22 to 24 are diagrams showing a peripheral circuit element according to some embodiments.

FIGS. 25 to 30 are diagrams for illustrating a shape and/or arrangement of the first bonding pad according to some embodiments.

FIG. 31 and FIG. 32 are diagrams for illustrating an arrangement of the first bonding pad and the second bonding pad according to some embodiments.

FIGS. 33 to 35 are diagrams for illustrating an arrangement of the bit line, the word-line, the shielding conductive line, and the back gate electrode according to some embodiments.

FIGS. 36 to 55 are diagrams for illustrating the arrangement of the bit-line, the shielding conductive line, the bit-line contact, and the shielding conductive line contact according to some embodiments.

FIGS. 56 to 61 are diagrams for illustrating the arrangement of the word-line, the back gate electrode, the word-line contact, and the back gate contact according to some embodiments.

FIGS. 62 to 65 are diagrams for illustrating an arrangement of the data storage pattern and the second cell contact structure according to some embodiments.

FIGS. 66 to 69 are diagrams for illustrating an arrangement relationship of the data storage pattern, the landing pattern, and the contact pattern according to some embodiments.

### DETAILED DESCRIPTIONS

Although terms such as first, second, upper, and lower are used herein to describe various elements or components, it is obvious that these element or components are not limited by the terms. Rather, the terms are merely used herein to distinguish one element or component from another element or component. Therefore, it is obvious that a first element or component as mentioned below may also be a second element or component within the technical spirit of the present disclosure. Further, it is obvious that a lower element or component as mentioned below may also be an upper element or component within the technical spirit of the present disclosure.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Hereinafter, embodiments of the present disclosure will be described in detail with reference to the accompanying drawings. The same reference numerals are used for the same components in the drawings, and duplicate descriptions thereof are omitted.

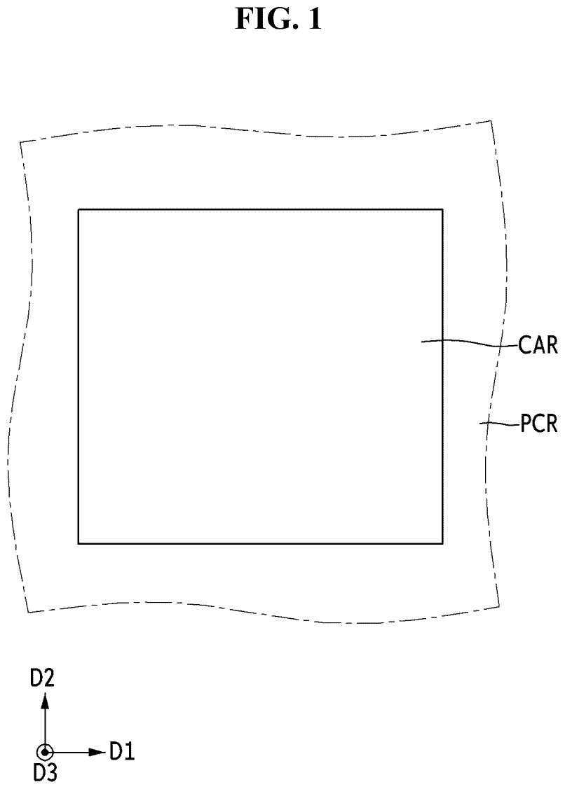

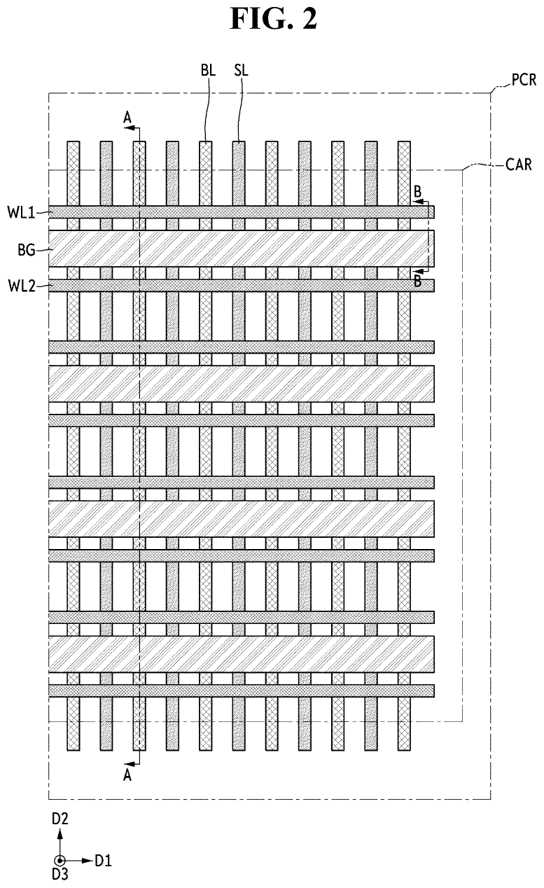

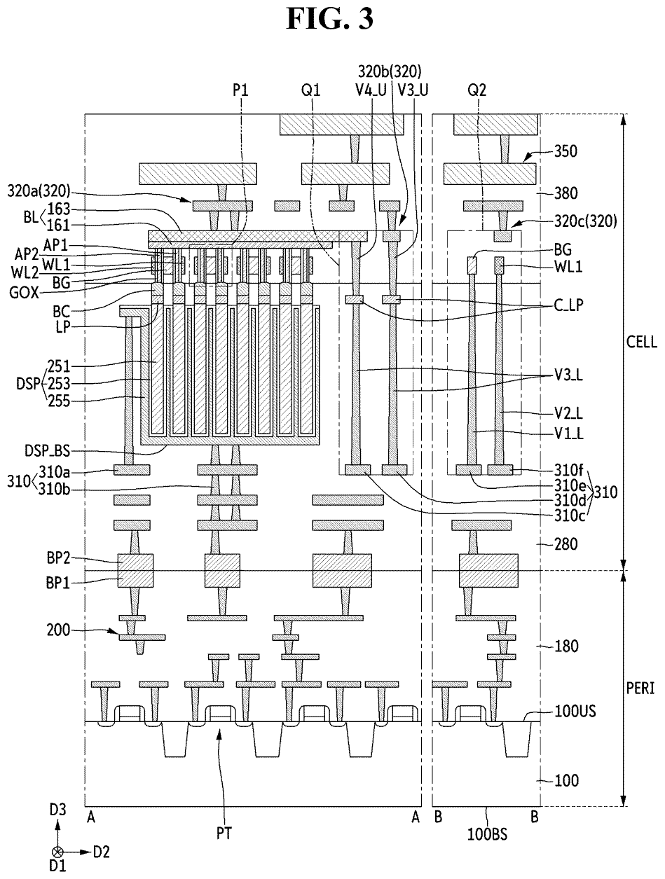

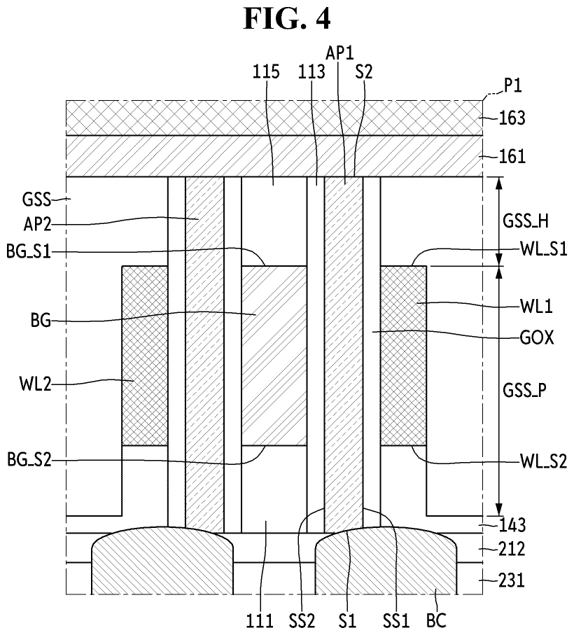

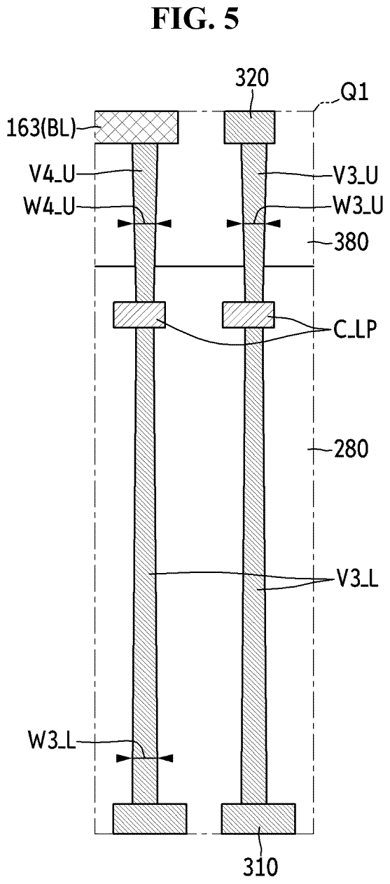

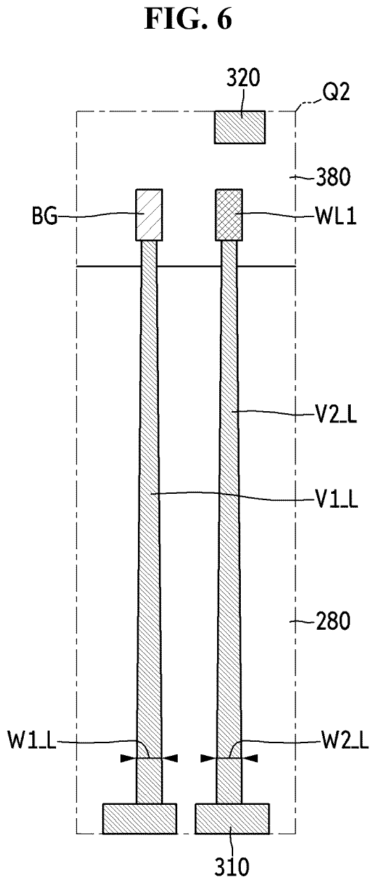

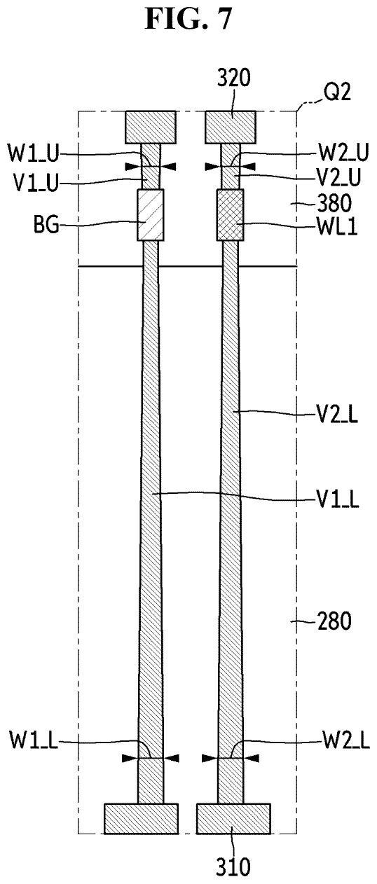

Hereinafter, with reference to FIGS. 1 to 7, a semiconductor memory device in accordance with some embodiments of the present disclosure is described. FIG. 1 is a layout diagram of a semiconductor memory device according to some embodiments of the present disclosure. FIG. 2 is a layout diagram of a boundary portion of a cell array area and a peripheral circuit area in FIG. 1. FIG. 3 is a cross-sectional view cut along lines A-A and B-B of FIG. 2. FIG. 4 is an enlarged view of a P1 portion of FIG. 3. FIG. 5 is an enlarged view of a Q1 portion of FIG. 3. FIG. 6 and FIG. 7 are enlarged views of a Q2 portion of FIG. 3.

A semiconductor memory device according to some embodiments of the present disclosure may include memory cells, each including a vertical channel transistor (VCT).

Referring to FIGS. 1 to 7, the semiconductor memory device according to some embodiments of the present disclosure may include a cell array area CAR and a cell peripheral circuit area PCR defined around the cell array area CAR. The semiconductor memory device according to some embodiments of the present disclosure may include a peripheral circuit structure PERI and a cell structure CELL.

The peripheral circuit structure PERI and the cell structure CELL may be stacked on top of each other in a third direction D3. In the present disclosure, the first direction D1, a second direction D2, and a third direction D3 may intersect each other. The first direction D1, the second direction D2, and the third direction D3 may be substantially perpendicular to each other.

The semiconductor memory device according to some embodiments may have a C2C (Chip to Chip) structure. In the C2C structure, an upper chip including the cell structure CELL is manufactured on a first wafer, and a lower chip (e.g., the peripheral circuit structure PERI) is manufactured on a second wafer which is different from the first wafer, and then the upper chip and the lower chip are connected to each other using a hybrid bonding process.

For example, the hybrid bonding process may refer to a scheme of electrically connecting a second bonding pad (BP2 in FIG. 3) formed in the upper chip to a first bonding pad (BP1 in FIG. 3) formed in the lower chip. For example, when each of the first bonding pad BP1 and the second bonding pad BP2 is made of copper (Cu), the bonding scheme may be a Cu—Cu hybrid bonding process. However, this is only an example, and the first bonding pad BP1 and the second bonding pad BP2 may be made of various other metals such as aluminum (Al) or tungsten (W).

The peripheral circuit structure PERI may include a peripheral circuit substrate 100, a peripheral circuit element PT, a peripheral circuit contact structure 200, and the first bonding pad BP1.

The peripheral circuit substrate 100 may include, for example, a semiconductor substrate such as a silicon substrate, germanium substrate, or silicon-germanium substrate. Alternatively, the peripheral circuit substrate 100 may include a silicon-on-insulator (SOI) substrate or a germanium-on-insulator (GOI) substrate.

The peripheral circuit substrate 100 may extend in the first direction D1 and the second direction D2. The peripheral circuit substrate 100 may include an upper surface 100US and a lower surface 100BS that are opposite to each other.

The peripheral circuit element PT may be formed on the upper surface 100US of the peripheral circuit substrate 100. The peripheral circuit element PT may constitute a peripheral circuit that controls an operation of the semiconductor memory device. For example, the peripheral circuit element PT may include a control logic, a row decoder, and a page buffer.

The peripheral circuit element PT may include, for example, a transistor. However, embodiments of the present disclosure are not limited thereto. For example, the peripheral circuit element PT may include various active elements such as transistors, as well as various passive elements such as capacitors, resistors, and inductors.

The peripheral circuit contact structure 200 may be disposed on the upper surface 100US of the peripheral circuit substrate 100. Alternatively, the peripheral circuit contact structure 200 may be disposed on the peripheral circuit element PT. For example, the first interlayer insulating film (e.g., layer) 180 may be formed on the upper surface 100US of the peripheral circuit substrate 100. The peripheral circuit contact structure 200 may be formed within the first interlayer insulating film 180 and may be electrically connected to the peripheral circuit element PT.

The first interlayer insulating film 180 may include, but is not limited to, at least one of silicon oxide, silicon oxynitride, and a low-k material with a dielectric constant smaller than that of silicon oxide.

The peripheral circuit contact structure 200 may include a plurality of vias. A width of each of the plurality of vias may increase as each via extends away from the upper surface 100US of the peripheral circuit substrate 100 in the third direction D3. For example, the width of each of the plurality of vias may decrease as each via extends away from the first bonding pad BP1, which will be described later, in the third direction D3. A width of each of the plurality of vias may decrease as each via extends away from a boundary between the peripheral circuit structure PERI and the cell structure CELL.

The first bonding pad BP1 may be connected to the second bonding pad BP2, which will be described later. The first bonding pad BP1 may be connected to the second bonding pad BP2 at the boundary between the peripheral circuit structure PERI and the cell structure CELL. Thus, the peripheral circuit element PT, a bit-line BL, an active pattern AP1 and AP2, a data storage pattern DSP, etc. may be electrically connected to each other.

The cell structure CELL may include the second bonding pad BP2, a first cell contact structure 310, the data storage pattern DSP, a landing pad LP, a contact pattern BC, the active patterns AP1 and AP2, word-lines WL1 and WL2, back gate electrodes BG, bit-lines BL, a contact landing pad C_LP, a second cell contact structure 320, and an upper wiring structure 350.

The second bonding pad BP2 may be disposed on the first bonding pad BP1 and within a second interlayer insulating film 280. The second bonding pad BP2 may be connected to and in contact with the first bonding pad BP1 and may connect the cell structure CELL and the peripheral circuit structure PERI to each other It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The first cell contact structure 310 may be disposed on the second bonding pad BP2. The first cell contact structure 310 may be disposed within the second interlayer insulating film 280. The first cell contact structure 310a, 310b, 310c, 310d, 310e, and 310f may be electrically connected to the data storage pattern DSP, the contact landing pad C_LP, the back gate electrode BG, and the first word-line WL1. A type, a location, and the number of the first cell contact structures 310 are not limited to those shown in FIG. 3 and may vary in various ways.

The data storage pattern DSP may be disposed on the first cell contact structure 310 and within the second interlayer insulating film 280.

For example, the data storage pattern DSP may be a capacitor. The data storage pattern DSP may include a capacitor dielectric layer 253 interposed between a storage electrode 251 and a plate electrode 255.

In a plan view, the storage electrode 251 may have various shapes, such as circular, oval, rectangular, square, diamond, or hexagonal shapes. Although not shown, the plate electrode 255 may be embodied as a double layer. For example, the plate electrode 255 may include an upper plate and a lower plate.

Each of the storage electrode 251 and the plate electrode 255 may include at least one of, for example, doped polysilicon, conductive metal nitride, conductive metal silicon nitride, metal carbonitride, conductive metal silicide, conductive metal oxide, and metal.

The capacitor dielectric layer 253 may include at least one of a ferroelectric material, an antiferroelectric material, and a paraelectric material. For example, the capacitor dielectric film 253 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material, and a paraelectric material.

Alternatively, each of the data storage patterns DSP may be embodied as a variable resistance pattern that may be switched to between two resistance states under an electrical pulse applied to a memory element. For example, each of the data storage patterns DSP may include a phase-change material having a crystal state varying depending on an amount of current, perovskite compounds, transition metal oxides, magnetic materials, ferromagnetic materials, or antiferromagnetic materials.

A bottom surface DSP_BS of the data storage pattern DSP may be a surface of the plate electrode 255. The bottom surface DSP_BS of the data storage pattern DSP may face an upper surface 100US of the peripheral circuit substrate 100.

The landing pads LP may be disposed on the data storage pattern DSP. Each of the landing pads LP may be disposed on each storage electrode 251. The storage electrode 251 may contact the landing pad LP. In a plan view, the landing pads LP may have various shapes such as circular, oval, rectangular, square, diamond, and hexagonal shapes. Although not shown, pad isolation insulation patterns may be disposed between the landing pads LP. The pad isolation insulation pattern may be made of an insulating material.

The data storage patterns DSP may entirely overlap or partially overlap the landing pads LP in the third direction D3, respectively. The data storage pattern DSP may contact an entirety or a portion of an upper surface of each of the landing pads LP.

The landing pad LP may include a conductive material. For example, each of the landing pads LP may include at least one of doped semiconductor material, conductive metal nitride, conductive metal silicon nitride, metal carbonitride, conductive metal silicide, conductive metal oxide, and two-dimensional material (2D material), metal and metal alloy. In the semiconductor memory device according to some embodiments, the two-dimensional material may be a metallic material and/or a semiconductor material. The two-dimensional material may include two-dimensional allotrope or two-dimensional compound. For example, the two-dimensional material may include, but is not limited to, at least one of graphene, molybdenum disulfide (MoS₂), molybdenum diselenide (MoSe₂), tungsten diselenide (WSe₂), and tungsten disulfide (WS₂). That is, the above-described two-dimensional materials are only listed by way of example. The two-dimensional material that may be included in the semiconductor device according to the present disclosure is not limited to the above-described materials.

The contact landing pad C_LP may be spaced apart from the landing pad LP in the second direction D2. The contact landing pad C_LP may be formed at the same vertical level as that of the landing pad LP. In this regard, “same vertical level” means being formed in the same manufacturing process. Therefore, the contact landing pad C_LP may be disposed at the same vertical level as that of the landing pad LP. The contact landing pad C_LP may include a conductive material. The conductive material included in the contact landing pad C_LP may be the same as the material included in the landing pad LP as described above.

In FIG. 3, it is shown that there are two contact landing pads C_LP. However, the technical idea of the present disclosure is not limited thereto. The number and arrangement of contact landing pads C_LP may vary depending on the manufacturing process. The contact landing pad C_LP may be disposed on the cell peripheral circuit area PCR of the peripheral circuit substrate 100. The contact landing pad C_LP may be disposed at a vertical level lower than a vertical level of each of the active pattern AP1 and AP2, the back gate electrode BG, and the word-line WL1 and WL2. For example, the contact landing pad C_LP may be disposed at a lower vertical level than that of each of the back gate electrode BG and the word-line WL1 and WL2 based on the second bonding pad BP2.

The contact pattern BC may be disposed on the landing pad LP. The contact patterns BC may be connected to the first active pattern AP1 and the second active pattern AP2, respectively. In a plan view, each contact pattern BC may have various shapes such as circular, oval, rectangular, square, diamond, or hexagon shape.

The contact pattern BC may include a conductive material. The contact pattern BC may include, for example, at least one of doped polysilicon, conductive metal nitride, conductive metal silicon nitride, metal carbonitride, conductive metal silicide, conductive metal oxide, two-dimensional material, and metal.

As illustrated in FIG. 4, the contact patterns BC may extend through a contact interlayer insulating film 231 and an etch stop film 212. When pad isolation insulation patterns are disposed between the landing pads LP, the contact interlayer insulating film 231 and the etch stop film 212 may be disposed on the pad isolation insulation patterns. Each of the contact interlayer insulating film 231 and the etch stop film 212 may be made of an insulating material.

The first active patterns AP1 and the second active patterns AP2 may be disposed on the second bonding pad BP2. The first active patterns AP1 and the second active patterns AP2 may be disposed on the data storage pattern DSP. The data storage patterns DSP may be disposed between the first active pattern AP1 and the first cell contact structure 310. The data storage patterns DSP may be disposed between the second active pattern AP2 and the first cell contact structure 310. The first active patterns AP1 and the second active patterns AP2 may be alternately arranged with each other along the second direction D2.

The first active patterns AP1 may be spaced apart from each other in the first direction D1. The first active pattern AP1 may be spaced apart from each other by an equal spacing. The second active patterns AP2 may be spaced apart from each other in the first direction D1. The second active patterns AP2 may be spaced apart from each other by an equal spacing. The first active pattern AP1 may be spaced apart from the second active pattern AP2 in the second direction D2. The first active patterns AP1 and the second active patterns AP2 may be arranged two-dimensionally along the first direction D1 and the second direction D2.

For example, each of the first active pattern AP1 and the second active pattern AP2 may be made of a single crystal semiconductor material. For example, each of the first active pattern AP1 and the second active pattern AP2 may be made of single crystal silicon.

In FIG. 4, each of the first active pattern AP1 and the second active pattern AP2 may include a first surface S1 and a second surface S2 that are opposite to each other in the third direction D3. For example, the first surface S1 of each of the first and second active patterns AP1 and AP2 may face the contact pattern BC. The first surface S1 of each of the first and second active patterns AP1 and AP2 may be connected to the contact patterns BC. The second surface S2 of each of the first and second active patterns AP1 and AP2 may face the bit-line BL.

Each of the first active pattern AP1 and the second active pattern AP2 may include a first sidewall SS1 and a second sidewall SS2 that are opposite to each other in the second direction D2. The second sidewall SS2 of the first active pattern AP1 may face the first sidewall SS1 of the second active pattern AP2.

The first sidewall SS1 of the first active pattern AP1 may be adjacent to the first word-line WL1. The second sidewall SS2 of the second active pattern AP2 may be adjacent to the second word-line WL2.

The back gate electrodes BG may be disposed on the data storage pattern DSP. The back gate electrode BG may be disposed on the contact patterns BC. The data storage patterns DSP may be disposed between the back gate electrode BG and the first bonding pad BP1. The data storage patterns DSP may be disposed between the back gate electrode BG and the first cell contact structure 310.

The back gate electrodes BG may be spaced apart from each other in the second direction D2. The back gate electrodes BG may be spaced apart from each other by an equal spacing.

Each back gate electrode BG may be disposed between the first active pattern AP1 and the second active pattern AP2 adjacent to each other in the second direction D2. For example, the first active pattern AP1 may be disposed on one side of each back gate electrode BG, and the second active pattern AP2 may be disposed on the other side of each back gate electrode BG. A height in the third direction D3 of the back gate electrode BG may be smaller than a height in the third direction D3 of each of the first and second active patterns AP1 and AP2.

Each back gate electrode BG may be disposed between the second sidewall SS2 of the first active pattern AP1 and the first sidewall SS1 of the second active pattern AP2. Each back gate electrode BG may be disposed on the second sidewall SS2 of the first active pattern AP1 and the first sidewall SS1 of the second active pattern AP2.

The first active pattern AP1 may be disposed between the first word-line WL1 and the back gate electrode BG. The second active pattern AP2 may be disposed between the second word-line WL2 and the back gate electrode BG. A pair of the first word-line WL1 and the second word-line WL2 may be disposed between back gate electrodes BG adjacent to each other in the second direction D2.

The back gate electrode BG may include a first surface BG_S1 and a second surface BG_S2 which are opposite to each other in the third direction D3. The second surface BG_S2 of the back gate electrode is closer to the data storage pattern DSP than the first surface BG_S1 of the back gate electrode BG is.

The back gate electrode BG may include a conductive material, such as at least one of doped polysilicon, conductive metal nitride, conductive metal silicon nitride, metal carbonitride, conductive metal silicide, conductive metal oxide, two-dimensional material, and metal. When the semiconductor memory device operates, a voltage may be applied to the back gate electrode BG, so that a threshold voltage of the vertical channel transistor may be adjusted. The threshold voltage of the vertical channel transistor may be adjusted such that the leakage current characteristics may be prevented from being deteriorated.

A back gate isolation pattern 111 may be disposed between the first active pattern AP1 and the second active pattern AP2 adjacent to each other in the second direction D2. The back gate isolation pattern 111 may extend in the first direction D1 and in a parallel manner to the back gate electrode BG. The back gate isolation pattern 111 may be disposed on the second surface BG_S2 of the back gate electrode.

The back gate isolation pattern 111 may be made of an insulating material. The back gate isolation pattern 111 may include, for example, a silicon oxide film, a silicon oxynitride film, or a silicon nitride film. However, embodiments of the present disclosure are not limited thereto. For example, the back gate isolation pattern 111 may be formed at the same vertical level as that of the gate capping pattern 143, which will be described later. In this regard, “same vertical level” means being formed in the same manufacturing process. The back gate isolation pattern 111 may be made of the same material as that of the gate capping pattern 143.

A back gate insulating pattern 113 may be disposed between the back gate electrode BG and the first active pattern AP1 and between the back gate electrode BG and the second active pattern AP2. The back gate insulating pattern 113 may be disposed between the back gate isolation pattern 111 and the first active pattern AP1 and between the back gate isolation pattern 111 and the second active pattern AP2.

The back gate insulating pattern 113 may be made of an insulating material. The back gate insulating pattern 113 may include, for example, a silicon oxide film, a silicon oxynitride film, a high dielectric constant insulating film having a higher dielectric constant than the silicon oxide film, or a combination thereof.

A back gate capping pattern 115 may be disposed on the first surface BG_S1 of the back gate electrode BG. The back gate capping pattern 115 may be disposed between the bit-line BL and the back gate electrode BG. The back gate capping pattern 115 may be disposed between the first active pattern AP1 and the second active pattern AP2 adjacent to each other in the second direction D2. The back gate capping pattern 115 may extend in the first direction D1 and in a parallel manner to the back gate electrode BG.

The back gate capping pattern 115 may be made of an insulating material. For example, the back gate capping pattern 115 may include at least one of a silicon oxide film, a silicon oxynitride film, and a silicon nitride film.

The first word-line WL1 and the second word-line WL2 may be disposed on the data storage pattern DSP. The first word-line WL1 and the second word-line WL2 may be disposed on the contact patterns BC. The data storage patterns DSP may be disposed between the first word-line WL1 and the second bonding pad BP2. The data storage patterns DSP may be disposed between the second word-line WL2 and the second bonding pad BP2.

Each of the first word-line WL1 and the second word-line WL2 may extend in the first direction D1. The first word-lines WL1 and the second word-lines WL2 may be arranged alternately with each other in the second direction D2.

The first word-line WL1 may be disposed on the first sidewall SS1 of the first active pattern AP1. The second word-line WL2 may be disposed on the second sidewall SS2 of the second active pattern AP2. The first active patterns AP1 and the second active patterns AP2 may be disposed between the first word-line WL1 and the second word-line WL2 adjacent to each other in the second direction D2.

The first word-line WL1 and the second word-line WL2 may be spaced apart from the bit-line BL and the contact pattern BC in the third direction D3. The first word-line WL1 and the second word-line WL2 may be located between the bit-line BL and the contact pattern BC.

Each of the first word-line WL1 and the second word-line WL2 may include a first surface WL_S1 and a second surface WL_S2 opposite to each other in the third direction D3. The second surface WL_S2 of each of the first and second word-lines WL1 and WL2 is closer to the data storage pattern DSP than the first surface WL_S1 of each of the first and second word-lines WL1 and WL2 is.

The first word-line WL1 will be taken by way of example and will be described. For example, a height of the first word-line WL1 in the third direction D3 may be equal to a height of the back gate electrode BG in the third direction D3. In another example, the height of the first word-line WL1 in the third direction D3 may be greater than the height of the back gate electrode BG in the third direction D3. In still another example, the height of the first word-line WL1 in the third direction D3 may be smaller than the height of the back gate electrode BG in the third direction D3.

Moreover, in one example, based on the etch stop film 212, a vertical level of the first surface WL_S1 of the first word-line WL1 may be equal to a vertical level of the first surface BG_S1 of the back gate electrode BG. In another example, the vertical level of the first surface WL_S1 of the first word-line WL1 may be higher than the vertical level of the first surface BG_S1 of the back gate electrode BG. In still another example, the vertical level of the first surface WL_S1 of the first word-line WL1 may be lower than the vertical level of the first surface BG_S1 of the back gate electrode BG.

Moreover, in one example, based on the etch stop film 212, a vertical level of the second surface WL_S2 of the first word-line WL1 may be equal to the vertical level of the second surface BG_S2 of the back gate electrode BG. In another example, the vertical level of the second surface WL_S2 of the first word-line WL1 may be higher than the vertical level of the second surface BG_S2 of the back gate electrode BG. In still another example, the vertical level of the second surface WL_S2 of the first word-line WL1 may be lower than the vertical level of the second surface BG_S2 of the back gate electrode BG.

Each of the first word-line WL1 and the second word-line WL2 may include a conductive material. Each of the first word-line WL1 and the second word-line WL2 may include at least one of, for example, doped polysilicon, conductive metal nitride, conductive metal silicon nitride, metal carbonitride, conductive metal silicide, conductive metal oxide, a two-dimensional material, and a metal. Each of the first word-line WL1 and the second word-line WL2 is shown as being embodied as a single conductive film. However, this is only for convenience of illustration and embodiments of the present disclosure are not limited thereto.

The first surfaces WL_S1 of each of the first and second word-lines WL1 and WL2 may be flat. Unlike what is shown, in one example, the first surface WL_S1 of each of the first and second word-lines WL1 and WL2 may be concavely rounded. In another example, the first word-line WL1 and the second word-line WL2 may have a spacer form. For example, the first surfaces WL_S1 of each of the first and second word-lines WL1 and WL2 may be convexly rounded.

The second surface WL_S2 of each of the first and second word-lines WL1 and WL2 may be flat. Unlike what is shown, the second surface WL_S2 of each of the first and second word-lines WL1 and WL2 may be a concave curved surface. Each of the first surface BG_S1 of the back gate electrode BG and the second surface BG_S2 of the back gate electrode BG is shown as being flat. However, embodiments of the present disclosure are not limited thereto.

Gate insulation patterns GOX may be respectively disposed between the first word-line WL1 and the first active pattern AP1, and between the second word-line WL2 and the second active pattern AP2. The gate insulation pattern GOX may extend in the first direction D1 and in a parallel manner to the first word-line WL1 and the second word-line WL2. The gate insulation pattern GOX may contact the bit-line BL and may contact the contact pattern BC.

The gate insulation pattern GOX may include a silicon oxide film, a silicon oxynitride film, a high dielectric constant insulating film with a higher dielectric constant than that of the silicon oxide film, or a combination thereof.

The gate insulation pattern GOX may extend along the first sidewall SS1 of the first active pattern AP1 and may extend along the second sidewall SS2 of the second active pattern AP2. In the semiconductor memory device according to some embodiments, in a cross-sectional view, a portion of the gate insulation pattern GOX between the first active pattern AP1 and the first word-line WL1 may be isolated from a portion of the second gate insulation pattern GOX between the second active pattern AP2 and the second word-line WL2.

A gate capping pattern 143 may be disposed on the etch stop film 212 and the contact pattern BC. The gate capping pattern 143 may be disposed between the first word-line WL1 and the contact pattern BC, and between the second word-line WL2 and the contact pattern BC. The gate capping pattern 143 may cover the second surface WL_S2 of each of the first and second word-lines WL1 and WL2.

A gate isolation pattern GSS may be disposed on contact patterns BC. The gate isolation pattern GSS may be disposed between the bit-line BL and the contact pattern BC. The gate isolation pattern GSS may contact the bit-line BL.

The gate isolation pattern GSS may be disposed between the first word-line WL1 and the second word-line WL2 adjacent to each other in the second direction D2. The first word-line WL1 and the second word-line WL2 may be isolated from each other via the gate isolation pattern GSS. The gate isolation pattern GSS may extend in the first direction D1 while being disposed between the first word-line WL1 and the second word-line WL2.

The first word-line WL1 may be disposed between the gate isolation pattern GSS and the first active pattern AP1. The second word-line WL2 may be disposed between the gate isolation pattern GSS and the second active pattern AP2.

The gate isolation pattern GSS may include a horizontal portion GSS_H and a protrusion GSS_P. The protrusion GSS_P of the gate isolation pattern GSS may protrude in the third direction D3 from the horizontal portion GSS_H of the gate isolation pattern GSS. The protrusion GSS_P of the gate isolation pattern GSS may protrude from the horizontal portion GSS_H of the gate isolation pattern GSS toward the data storage pattern DSP.

The protrusion GSS_P of the gate isolation pattern GSS may be closer to the peripheral circuit substrate 100 than the horizontal portion GSS_H of the gate isolation pattern GSS may be. The horizontal portion GSS_H of the gate isolation pattern GSS may be closer to the bit-line BL than the protrusion GSS_P of the gate isolation pattern GSS may be.

The horizontal portion GSS_H of the gate isolation pattern GSS may contact the bit-line BL. A width of the horizontal portion GSS_H of the gate isolation pattern GSS in the second direction D2 is greater than a width of the protrusion GSS_P of the gate isolation pattern GSS in the second direction D2.

The protrusion GSS_P of the gate isolation pattern GSS may be disposed between a sidewall of the first word-line WL1 and a sidewall of the second word-line WL2 facing each other. The horizontal portion GSS_H of the gate isolation pattern GSS may cover the first surface WL_S1 of each of the first and second word-lines WL1 and WL2.

The horizontal portion GSS_H of the gate isolation pattern GSS may be disposed on the first word-line WL1 and the second word-line WL2. The horizontal portion GSS_H of the gate isolation pattern GSS may contact and extend along the first surface WL_S1 of each of the first word-line WL1 and the second word-line WL2. The first word-line WL1 and the second word-line WL2 may be disposed between the horizontal portion GSS_H of the gate isolation pattern GSS and the contact pattern BC.

The gate isolation pattern GSS may be made of an insulating material. Unlike what is shown, the gate isolation pattern GSS may include a plurality of insulating films (e.g., layers).

The bit-lines BL may be disposed on the first active pattern AP1 and the second active pattern AP2. The bit-lines BL may be disposed on the back gate electrode BG, the first word-line WL1, and the second word-line WL2.

Each bit-line BL may extend in the second direction D2 and across the back gate electrode BG. Adjacent bit-lines BL may be spaced apart from each other in the first direction D1. The bit-line BL may include a long sidewall extending in the second direction D2 and a short sidewall extending in the first direction D1.

Each bit-line BL may extend from the cell array area CAR of the peripheral circuit substrate 100 to the cell peripheral circuit area PCR. An end of each bit-line BL may be disposed on the cell peripheral circuit area PCR of the peripheral circuit substrate 100.

Each bit-line BL may include a semiconductor pattern 161 and a metal pattern 163 that are sequentially stacked. Unlike what is shown, the bit-line BL may include one of the semiconductor pattern 161 and the metal pattern 163.

The bit-line BL may include a conductive bit-line. Among the bit-lines BL, the conductive bit-line may include a film made of a conductive material. The conductive bit-line may include the semiconductor pattern 161 and the metal pattern 163.

The second surface S2 of each of the first and second active patterns AP1 and AP2 may be in contact with the bit-line BL. For example, the second surface S2 of each of the first and second active patterns AP1 and AP2 may be in contact with the semiconductor pattern 161. Unlike what is shown, when the semiconductor pattern 161 is omitted, the second surface S2 of each of the first and second active patterns AP1 and AP2 may contact the metal pattern 163.

The semiconductor pattern 161 may include a conductive semiconductor material. The semiconductor pattern 161 may include at least one of polysilicon, polysilicon germanium, poly germanium, amorphous silicon, amorphous silicon germanium, and amorphous germanium.

The metal pattern 163 may include a conductive material including a metal. For example, the metal pattern 163 may include at least one of conductive metal nitride, conductive metal silicon nitride, metal carbonitride, conductive metal silicide, conductive metal oxide, two-dimensional material, and metal.

As illustrated in FIG. 2, for example, a shielding conductive line SL is disposed adjacent to the bit-line BL. The shielding conductive line SL may be disposed adjacent to the bit-line BL in the first direction D1.

The shielding conductive line SL may be disposed between bit-lines BL adjacent to each other in the first direction D1. The shielding conductive line SL may extend in the second direction D2.

Although not shown, the shielding conductive line SL may be disposed on the first active pattern AP1 and the second active pattern AP2. The shielding conductive line SL may be disposed on the back gate electrode BG, the first word-line WL1, and the second word-line WL2.

The shielding conductive line SL may extend from the cell array area CAR of the peripheral circuit substrate 100 to the cell peripheral circuit area PCR thereof. An end of the shielding conductive line SL may be disposed on the cell peripheral circuit area PCR of the peripheral circuit substrate 100.

The shielding conductive line SL may include a conductive material. For example, the shielding conductive line SL may include at least one of conductive metal nitride, conductive metal silicon nitride, metal carbonitride, conductive metal silicide, conductive metal oxide, two-dimensional material, and metal.

When the shielding conductive line SL is disposed between bit-lines BL adjacent to each other in the first direction D1, coupling noise between the bit-lines BL may be reduced.

The second cell contact structures 320a, 320b, and 320c may be disposed within the third interlayer insulating film 380. The second cell contact structure 320 may be disposed on the bit-line BL. The second cell contact structure 320 may be disposed on the contact landing pad C_LP. The second cell contact structure 320 may be disposed on the back gate electrode BG and the word-line WL1 and WL2.

The second cell contact structures 320a, 320b, and 320c may be disposed within the third interlayer insulating film 380. The second cell contact structure 320 may be electrically connected to the bit-line BL, the contact landing pad C_LP, the back gate electrode BG, and the first word-line WL1. A type, location, and number of the second cell contact structures 320 are not limited to those shown in FIG. 3 and may vary in various ways.

Referring to FIG. 5, a third lower via V3_L may be disposed between the contact landing pad C_LP and the first cell contact structure 310. The third lower via V3_L may electrically connect the contact landing pad C_LP and the first cell contact structure 310 to each other. A width W3_L of the third lower via V3_L may decrease as the third lower via V3_L extends from the first cell contact structure 310 toward the contact landing pad C_LP. That is, the width W3_L of the third lower via V3_L may decrease as the third lower via V3_L extends away from the first cell contact structure 310 in the third direction D3. The width W3_L of the third lower via V3_L may decrease as the third lower via V3_L extends toward the contact landing pad C_LP in the third direction D3.

A third upper via V3_U may be disposed between the contact landing pad C_LP and the second cell contact structure 320. The third upper via V3_U may electrically connect the contact landing pad C_LP and the second cell contact structure 320 to each other. A width W3_U of the third upper via V3_U may decrease as the third upper via V3_U extends from the second cell contact structure 320 toward the contact landing pad C_LP. That is, the width W3_U of the third upper via V3_U may decrease as the third upper via V3_U extends away from the second cell contact structure 320 in the third direction D3. The width W3_U of the third upper via V3_U may decrease as the third upper via V3_U extends toward the contact landing pad C_LP in the third direction D3.

A fourth upper via V4_U may be disposed between the contact landing pad C_LP and the bit-line BL. The fourth upper via V4_U may electrically connect the contact landing pad C_LP and bit-line BL to each other. A width W4_U of the fourth upper via V4_U may decrease as the fourth upper via V4_U extends from the bit-line BL toward the contact landing pad C_LP. For example, the width W4_U of the fourth upper via V4_U may decrease as the fourth upper via V4_U extends away from the bit-line BL in the third direction D3. The width W4_U of the fourth upper via V4_U may decrease as the fourth upper via V4_U extends toward the contact landing pad C_LP in the third direction D3.

A length of the third lower via V3_L in the third direction D3 may be different from a length of the third upper via V3_U in the third direction D3 or a length of the fourth upper via V4_U in the third direction D3. For example, the length of the third lower via V3_L in the third direction D3 may be larger than the length of the third upper via V3_U in the third direction D3 or the length of the fourth upper via V4_U in the third direction D3. Alternatively, the length of the third lower via V3_L in the third direction D3 may be smaller than the length of the third upper via V3_U in the third direction D3 or the length of the fourth upper via V4_U in the third direction D3.

Referring to FIG. 6, a first lower via V1_L may be disposed between the back gate electrode BG and the first cell contact structure 310. The first lower via V1_L may electrically connect the back gate electrode BG and the first cell contact structure 310 to each other. A width W1_L of the first lower via V1_L may decrease as the first lower via V1_L extends from the first cell contact structure 310 toward the back gate electrode BG. That is, the width W1_L of the first lower via V1_L may decrease as the first lower via V1_L extends away from the first cell contact structure 310 in the third direction D3. The width W1_L of the first lower via V1_L may decrease as the first lower via V1_L extends toward the back gate electrode BG in the third direction D3.

A second lower via V2_L may be disposed between the first word-line WL1 and the first cell contact structure 310. The second lower via V2_L may electrically connect the first word-line WL1 and the first cell contact structure 310 to each other. A width W2_L of the second lower via V2_L may decrease as the second lower via V2_L extends from the first cell contact structure 310 toward the first word-line WL1. For example, the width W2_L of the second lower via V2_L may decrease as the second lower via V2_L extends away from the first cell contact structure 310 in the third direction D3. The width W2_L of the second lower via V2_L may decrease as the second lower via V2_L extends toward the first word-line WL1 in the third direction D3.

Referring to FIG. 7, a first upper via V1_U may be disposed between the back gate electrode BG and the second cell contact structure 320. The first upper via V1_U may electrically connect the back gate electrode BG and the second cell contact structure 320 to each other. A width W1_U of the first upper via V1_U may decrease as the first upper via V1_U extends from the second cell contact structure 320 toward the back gate electrode BG. For example, the width W1_U of the first upper via V1_U may decrease as the first upper via V1_U extends away from the second cell contact structure 320 in the third direction D3. The width W1_U of the first upper via V1_U may decrease as the first upper via V1_U extends toward the back gate electrode BG in the third direction D3.

A second upper via V2_U may be disposed between the first word-line WL1 and the second cell contact structure 320. The second upper via V2_U may electrically connect the first word-line WL1 and the second cell contact structure 320 to each other. A width W2_U of the second upper via V2_U may decrease as the second upper via V2_U extends from the second cell contact structure 320 toward the first word-line WL1. For example, the width W2_U of the second upper via V2_U may decrease as the second upper via V2_U extends away from the second cell contact structure 320 in the third direction D3. The width W2_U of the second upper via V2_U may decrease as the second upper via V2_U extends toward the first word-line WL1 in the third direction D3.

A length of the first lower via V1_L in the third direction D3 may be different from a length of the first upper via V1_U in the third direction D3. For example, the length of the first lower via V1_L in the third direction D3 may be greater than the length of the first upper via V1_U in the third direction D3. Alternatively, the length of the first lower via V1_L in the third direction D3 may be smaller than the length of the first upper via V1_U in the third direction D3.

A length of the second lower via V2_L in the third direction D3 may be different from a length of the second upper via V2_U in the third direction D3. For example, the length of the second lower via V2_L in the third direction D3 may be greater than the length of the second upper via V2_U in the third direction D3. Alternatively, the length of the second lower via V2_L in the third direction D3 may be smaller than the length of the second upper via V2_U in the third direction D3.

A width W1_L of the first lower via V1_L and a width W1_U of the first upper via V1_U may be different. For example, the width W1_U of the first upper via V1_U based on the upper surface of the back gate electrode BG may be different from the width W1_L of the first lower via V1_L based on the lower surface of the back gate electrode BG.

A width W2_L of the second lower via V2_L and a width W2_U of the second upper via V2_U may be different. For example, the width W2_U of the second upper via V2_U based on the upper surface of the first-word line WL1 may be different from the width W2_L of the second lower via V2_L based on the lower surface of the first-word line WL1.

Each of the first to third lower vias V1_L, V2_L, and V3_L and the first to fourth upper vias V1_U, V2_U, V3_U, and V4_U include a conductive material. Each f the first to third lower vias V1_L, V2_L, and V3_L and the first to fourth upper vias V1_U, V2_U, V3_U, and V4_U may include at least one of, for example, a doped semiconductor material, a conductive metal nitride, a conductive metal silicon nitride, metal carbonitride, conductive metal silicide, conductive metal oxide, two-dimensional material, and metal. Each of the first to third lower vias V1_L, V2_L, and V3_L and the first to fourth upper vias V1_U, V2_U, V3_U, and V4_U is shown as being embodied as a single film. However, embodiments of the present disclosure are not limited thereto.

The upper wiring structure 350 may be disposed on the second cell contact structure 320. The upper wiring structure 350 may be disposed within the third interlayer insulating film 380. The upper wiring structure 350 may be electrically connected to the second cell contact structure 320. The upper wiring structure 350 may include a conductive material.

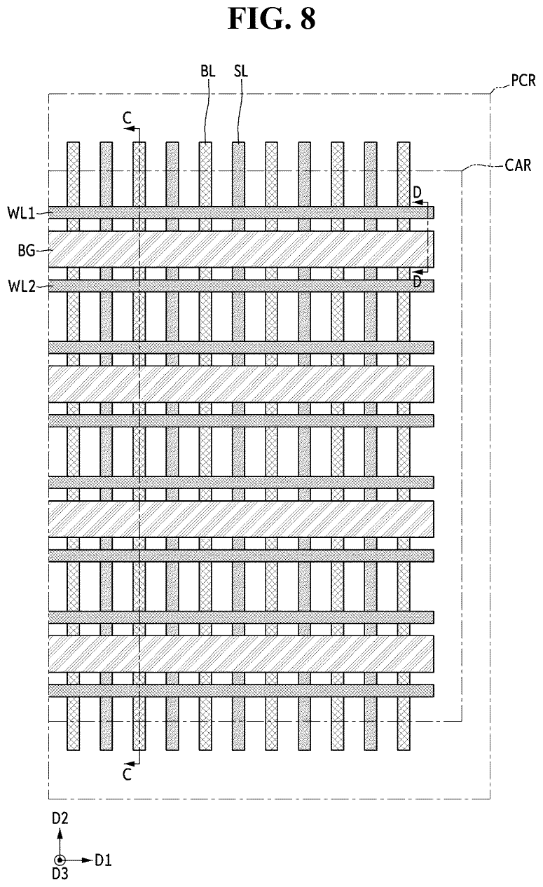

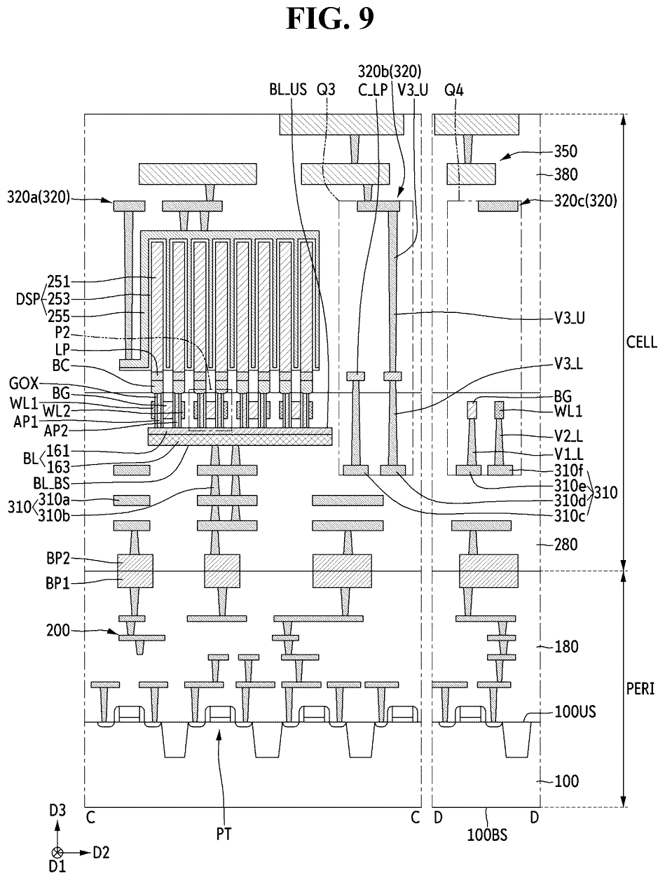

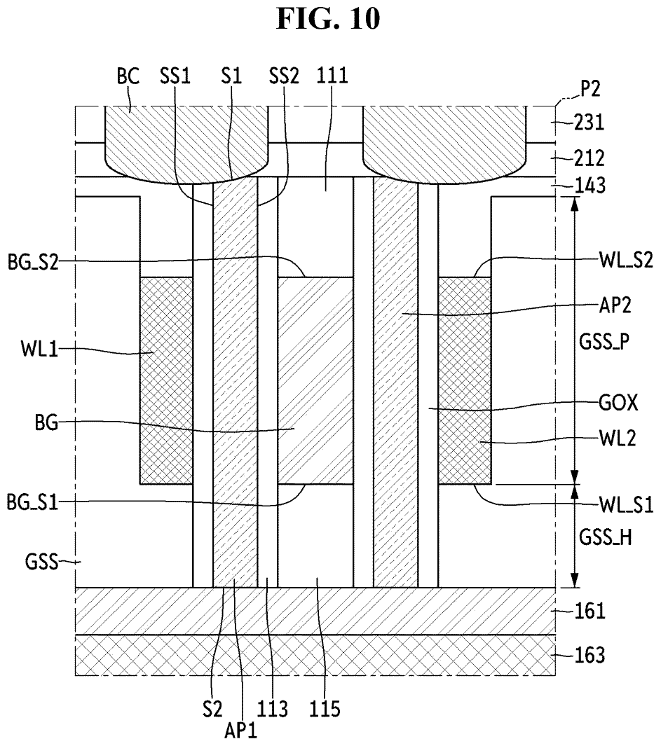

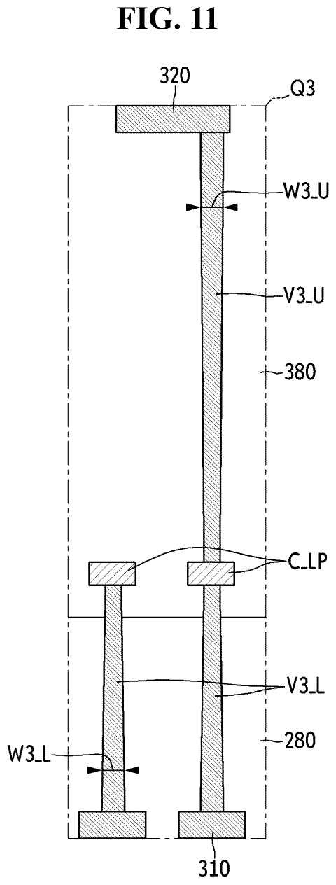

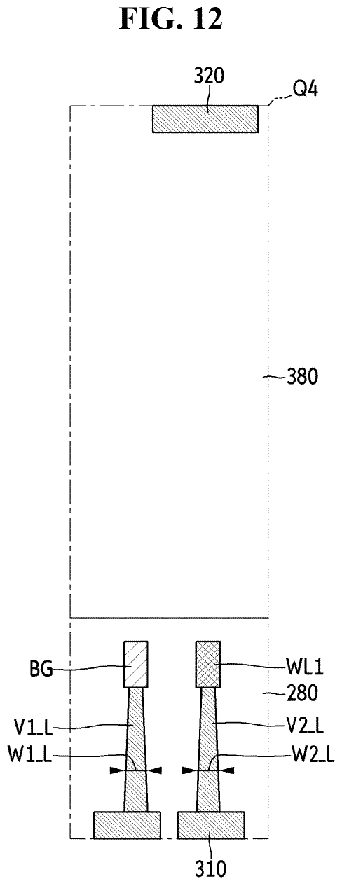

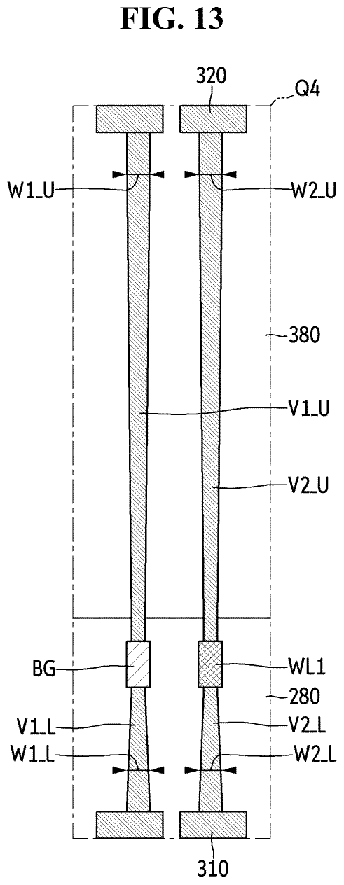

FIG. 8 is a layout diagram of a boundary portion of the cell array area and the peripheral circuit area in FIG. 1. FIG. 9 is a cross-sectional view cut along C-C and D-D in FIG. 8. FIG. 10 is an enlarged view of a P2 portion of FIG. 9. FIG. 11 is an enlarged view of a Q3 portion of FIG. 9. FIG. 12 and FIG. 13 are enlarged views of a Q4 portion of FIG. 9. For convenience of description, contents that duplicate with what have been described above with reference to FIGS. 1 to 7 are briefly described or the descriptions thereof are omitted.

Referring to FIGS. 8 to 13, a semiconductor memory device according to some embodiments of the present disclosure may include the peripheral circuit structure PERI and the cell structure CELL.

The peripheral circuit structure PERI may include the peripheral circuit substrate 100, the peripheral circuit element PT, the peripheral circuit contact structure 200, and the first bonding pad BP1. The descriptions about the peripheral circuit substrate 100, the peripheral circuit element PT, the peripheral circuit contact structure 200, and the first bonding pad BP1 may be substantially the same as those as set forth above using FIGS. 1 to 7.

The cell structure CELL may include the second bonding pad BP2, the first cell contact structure 310, the bit-lines BL, the active patterns AP1 and AP2, the word-lines WL1 and WL2, the back gate electrodes BG, the contact pattern BC, the landing pad LP, the contact landing pad C_LP, the data storage pattern DSP, the second cell contact structure 320, and the upper wiring structure 350.

The second bonding pad BP2 may be disposed on the first bonding pad BP1 and within the second interlayer insulating film 280. The second bonding pad BP2 may be connected to and in contact with the first bonding pad BP1 and may connect the cell structure CELL and the peripheral circuit structure PERI to each other.

The first cell contact structure 310 may be disposed on the second bonding pad BP2. The first cell contact structure 310a, 310b, 310c, 310d, 310e, and 310f may be electrically connected to the bit-line BL, the back gate electrode BG, the first word-line WL1, and the contact landing pad C_LP.

The bit-line BL may be disposed on the first cell contact structure 310 and within the second interlayer insulating film 280. The bit-line BL may include the lower surface BL_BS facing the upper surface 100US of the peripheral circuit substrate 100 and the upper surface BL_US opposite to the lower surface BL_BS. The bit-line BL may include the semiconductor pattern 161 and the metal pattern 163. The bit-line BL may extend in the second direction D2. Adjacent bit-lines BL may be spaced apart from each other in the first direction D1.

As illustrated in FIG. 8, for example, the shielding conductive line SL is disposed adjacent to the bit-line BL. The shielding conductive line SL may be disposed adjacent to the bit-line BL in the first direction D1.

Each of the first active patterns AP1 and the second active patterns AP2 may be disposed on the upper surface BL_US of the bit-line BL. The first active patterns AP1 and the second active patterns AP2 may be alternately arranged with each other along the second direction D2.

Each of the first active pattern AP1 and the second active pattern AP2 may include the first surface S1 and the second surface S2 opposite to each other in the third direction D3. The second surface S2 of the first and second active patterns AP1 and AP2 may be connected to the upper surface BL_US of the bit-line BL. For example, the second surface S2 of the first and second active patterns AP1 and AP2 may be connected to the semiconductor pattern 161 of the bit-line BL. The first surface S1 of each of the first and second active patterns AP1 and AP2 may be connected to the contact pattern BC.

Each of the first active pattern AP1 and the second active pattern AP2 may include the first sidewall SS1 and the second sidewall SS2 that are opposite to each other in the second direction D2. The second sidewall SS2 of the first active pattern AP1 may face the first sidewall SS1 of the second active pattern AP2.

The first sidewall SS1 of the first active pattern AP1 may be adjacent to the first word-line WL1. The second sidewall SS2 of the second active pattern AP2 may be adjacent to the second word-line WL2.

The back gate electrodes BG may be disposed on the bit-line BL. The back gate electrodes BG may be spaced apart from each other in the second direction D2. The back gate electrodes BG may be spaced apart from each other by an equal spacing. Each back gate electrode BG may be disposed between the first active pattern AP1 and the second active pattern AP2 adjacent to each other in the second direction D2. Each back gate electrode BG may be disposed between the second sidewall SS2 of the first active pattern AP1 and the first sidewall SS1 of the second active pattern AP2.

The first active pattern AP1 may be disposed between the first word-line WL1 and the back gate electrode BG. The second active pattern AP2 may be disposed between the second word-line WL2 and the back gate electrode BG.

The back gate electrode BG may include the first surface BG_S1 and the second surface BG_S2 which are opposite to each other in the third direction D3. The first surface BG_S1 of the back gate electrode BG is closer to the bit-line BL than the second surface BG_S2 of the back gate electrode BG is.

The back gate isolation pattern 111 may be disposed between the first active pattern AP1 and the second active pattern AP2 adjacent to each other in the second direction D2. The back gate isolation pattern 111 may extend in the first direction D1 and in a parallel manner to the back gate electrode BG. The back gate isolation pattern 111 may be disposed on the second surface BG_S2 of the back gate electrode.

The back gate capping pattern 115 may be disposed on the first surface BG_S1 of the back gate electrode BG. The back gate capping pattern 115 may be disposed between the bit-line BL and the back gate electrode BG. The back gate capping pattern 115 may be disposed between the first active pattern AP1 and the second active pattern AP2 adjacent to each other in the second direction D2. The back gate capping pattern 115 may extend in the first direction D1 and in a parallel manner to the back gate electrode BG.

The first word-line WL1 and the second word-line WL2 may be disposed on the bit-line BL.

Each of the first word-line WL1 and the second word-line WL2 may extend in the first direction D1. The first word-lines WL1 and the second word-lines WL2 may be arranged alternately with each other in the second direction D2.

The first word-line WL1 may be disposed on the first sidewall SS1 of the first active pattern AP1. The second word-line WL2 may be disposed on the second sidewall SS2 of the second active pattern AP2. The first active patterns AP1 and the second active patterns AP2 may be disposed between the first word-line WL1 and the second word-line WL2 adjacent to each other in the second direction D2.

The first word-line WL1 and the second word-line WL2 may be spaced apart from the bit-line BL and the contact pattern BC in the third direction D3. The first word-line WL1 and the second word-line WL2 may be located between the bit-line BL and the contact pattern BC.

Each of the first word-line WL1 and the second word-line WL2 may include the first surface WL_S1 and the second surface WL_S2 opposite to each other in the third direction D3. The first surface WL_S1 of each of the first and second word-lines WL1 and WL2 is closer to the bit-line BL than the second surface WL_S2 of each of the first and second word-lines WL1 and WL2 is.

The gate insulation patterns GOX may be respectively disposed between the first word-line WL1 and the first active pattern AP1, and between the second word-line WL2 and the second active pattern AP2. The gate insulation pattern GOX may extend in the first direction D1 and in a parallel manner to the first word-line WL1 and the second word-line WL2.

The gate insulation pattern GOX may contact the bit-line BL and may contact the contact pattern BC.

The gate capping pattern 143 may be disposed between the first word-line WL1 and the contact pattern BC, and between the second word-line WL2 and the contact pattern BC. The gate capping pattern 143 may cover the second surface WL_S2 of each of the first and second word-lines WL1 and WL2.

The gate isolation pattern GSS may be disposed on the bit-line BL. The gate isolation pattern GSS may be disposed between the bit-line BL and the contact pattern BC. The gate isolation pattern GSS may contact the bit-line BL.

The gate isolation pattern GSS may be disposed between the first word-line WL1 and the second word-line WL2 adjacent to each other in the second direction D2. The first word-line WL1 and the second word-line WL2 may be isolated from each other via the gate isolation pattern GSS. The gate isolation pattern GSS may extend in the first direction D1 while being disposed between the first word-line WL1 and the second word-line WL2.

The first word-line WL1 may be disposed between the gate isolation pattern GSS and the first active pattern AP1. The second word-line WL2 may be disposed between the gate isolation pattern GSS and the second active pattern AP2.

The gate isolation pattern GSS may include the horizontal portion GSS_H and protrusion GSS_P. The protrusion GSS_P of the gate isolation pattern GSS may protrude in the third direction D3 from the horizontal portion GSS_H of the gate isolation pattern GSS.

The horizontal portion GSS_H of the gate isolation pattern GSS may be closer to the peripheral circuit substrate 100 than the protrusion GSS_P of the gate isolation pattern GSS may be. The protrusion GSS_P of the gate isolation pattern GSS may be closer to the data storage pattern DSP than the horizontal portion GSS_H of the gate isolation pattern GSS may be.

The protrusion GSS_P of the gate isolation pattern GSS may be disposed between the sidewall of the first word-line WL1 and the sidewall of the second word-line WL2 facing each other. The horizontal portion GSS_H of the gate isolation pattern GSS may cover the first surface WL_S1 of each of the first and second word-lines WL1 and WL2.

The first word-line WL1 and the second word-line WL2 may be disposed on the horizontal portion GSS_H of the gate isolation pattern GSS. The horizontal portion GSS_H of the gate isolation pattern GSS may contact and extend along the first surface WL_S1 of each of the first word-line WL1 and the second word-line WL2. The first word-line WL1 and the second word-line WL2 may be disposed between the horizontal portion GSS_H of the gate isolation pattern GSS and the contact pattern BC.

The gate isolation pattern GSS may be made of an insulating material. Unlike what is shown, the gate isolation pattern GSS may include a plurality of insulating films.

The contact patterns BC may extend through the contact interlayer insulating film 231 and the etch stop film 212. The contact patterns BC may be connected to the first active pattern AP1 and the second active pattern AP2, respectively. Each of the contact patterns BC may be connected to the first surface S1 of each of the first and second active patterns AP1 and AP2. The contact pattern BC may include a conductive material.

The landing pad LP may be disposed on the contact pattern BC. Although not shown, pad isolation insulation patterns may be disposed between the landing pads LP. The landing pads LP may include a conductive material.

The contact landing pad C_LP may be spaced apart from the landing pad LP in the second direction D2. The contact landing pad C_LP may be formed at the same vertical level as that of the landing pad LP. The contact landing pad C_LP may be disposed at a vertical level higher than a vertical level of each of the active pattern AP1 and AP2, the back gate electrode BG, and the word-line WL1 and WL2. For example, the contact landing pad C_LP may be disposed at a higher vertical level than a vertical level of each of the back gate electrode BG and the word-line WL1 and WL2 based on the second bonding pad BP2.

The data storage pattern DSP may be disposed on the landing pad LP. The data storage pattern DSP may be electrically connected to the first and second active patterns AP1 and AP2. The data storage pattern DSP may be a capacitor. The data storage pattern DSP may include the storage electrode 251, the plate electrode 255, and the capacitor dielectric layer 253.

The second cell contact structure 320 may be disposed within the third interlayer insulating film 380. The second cell contact structure 320 may be disposed on the data storage pattern DSP. The second cell contact structure 320 may be disposed on the contact landing pad C_LP. The second cell contact structure 320 may be disposed on the back gate electrode BG. The second cell contact structure 320 may be disposed on the first word-line WL1.

Referring to FIG. 11, the third lower via V3_L may be disposed between the contact landing pad C_LP and the first cell contact structure 310. The third lower via V3_L may electrically connect the contact landing pad C_LP and the first cell contact structure 310 to each other. The width W3_L of the third lower via V3_L may decrease as the third lower via V3_L extends from the first cell contact structure 310 toward the contact landing pad C_LP.

The third upper via V3_U may be disposed between the contact landing pad C_LP and the second cell contact structure 320. The third upper via V3_U may electrically connect the contact landing pad C_LP and the second cell contact structure 320 to each other. The width W3_U of the third upper via V3_U may decrease as the third upper via V3_U extends from the second cell contact structure 320 toward the contact landing pad C_LP.

The length of the third lower via V3_L in the third direction D3 may be different from the length of the third upper via V3_U in the third direction D3. For example, the length of the third lower via V3_L in the third direction D3 may be greater than the length of the third upper via V3_U in the third direction D3. Alternatively, the length of the third lower via V3_L in the third direction D3 may be smaller than the length of the third upper via V3_U in the third direction D3.

Referring to FIG. 12, the first lower via V1_L may be disposed between the back gate electrode BG and the first cell contact structure 310. The first lower via V1_L may electrically connect the back gate electrode BG and the first cell contact structure 310 to each other. The width W1_L of the first lower via V1_L may decrease as the first lower via V1_L extends from the first cell contact structure 310 toward the back gate electrode BG.

The second lower via V2_L may be disposed between the first word-line WL1 and the first cell contact structure 310. The second lower via V2_L may electrically connect the first word-line WL1 and the first cell contact structure 310 to each other. The width W2_L of the second lower via V2_L may decrease as the second lower via V2_L extends from the first cell contact structure 310 toward the first word-line WL1.

Referring to FIG. 13, the first upper via V1_U may be disposed between the back gate electrode BG and the second cell contact structure 320. The first upper via V1_U may electrically connect the back gate electrode BG and the second cell contact structure 320 to each other. The width W1_U of the first upper via V1_U may decrease as the first upper via V1_U extends from the second cell contact structure 320 toward the back gate electrode BG.

The second upper via V2_U may be disposed between the first word-line WL1 and the second cell contact structure 320. The second upper via V2_U may electrically connect the first word-line WL1 and the second cell contact structure 320 to each other. The width W2_U of the second upper via V2_U may decrease as the second upper via V2_U extends from the second cell contact structure 320 toward the first word-line WL1.

The length of the first lower via V1_L in the third direction D3 may be different from the length of the first upper via V1_U in the third direction D3. For example, the length of the first lower via V1_L in the third direction D3 may be smaller than the length of the first upper via V1_U in the third direction D3. Alternatively, the length of the first lower via V1_L in the third direction D3 may be greater than the length of the first upper via V1_U in the third direction D3.

The length of the second lower via V2_L in the third direction D3 may be different from the length of the second upper via V2_U in the third direction D3. For example, the length of the second lower via V2_L in the third direction D3 may be smaller than the length of the second upper via V2_U in the third direction D3. Alternatively, the length of the second lower via V2_L in the third direction D3 may be greater than the length of the second upper via V2_U in the third direction D3.

A width W1_L of the first lower via V1_L and a width W1_U of the first upper via V1_U may be different. For example, the width W1_U of the first upper via V1_U based on the upper surface of the back gate electrode BG may be different from the width W1_L of the first lower via V1_L based on the lower surface of the back gate electrode BG.

A width W2_L of the second lower via V2_L and a width W2_U of the second upper via V2_U may be different. For example, the width W2_U of the second upper via V2_U based on the upper surface of the first-word line WL1 may be different from the width W2_L of the second lower via V2_L based on the lower surface of the first-word line WL1.

The upper wiring structure 350 may be disposed on the second cell contact structure 320. The upper wiring structure 350 may be disposed within the third interlayer insulating film 380.

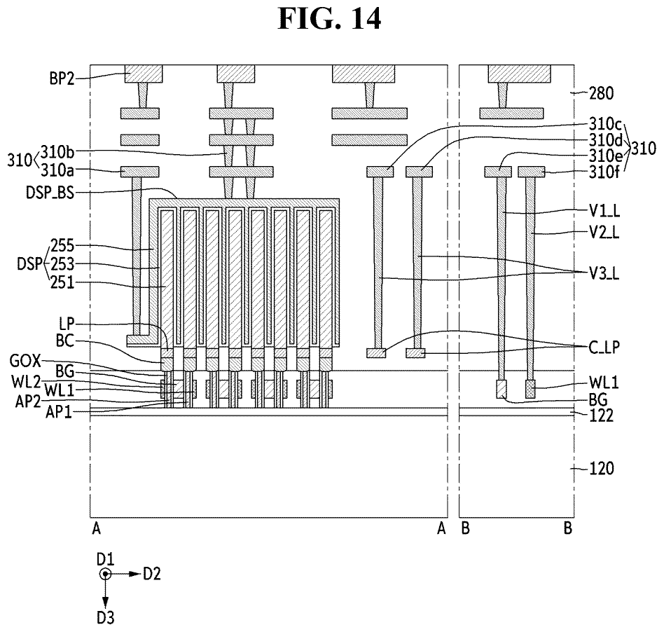

FIGS. 14 to 17 are diagrams for illustrating a semiconductor memory device manufacturing method according to some embodiments of the present disclosure. FIGS. 14 to 17 are diagrams for illustrating the method for manufacturing the semiconductor memory device as shown in FIG. 3. FIGS. 14 to 17 are cross-sectional views cut along A-A and B-B of FIG. 2. For convenience of description, contents duplicate with what have been set forth above using FIGS. 1 to 13 are briefly described or the descriptions thereof are omitted.

Referring to FIG. 14, a first sub-substrate 120 and a buried insulating layer 122 may be provided. The first sub-substrate 120 may be, for example, a silicon substrate, a germanium substrate, and/or a silicon-germanium substrate.

The buried insulating layer 122 may be a buried oxide (BOX) formed by a separation by implanted oxygen (SIMOX) method or a bonding and layer transfer method. Alternatively, the buried insulating layer 301 may be an insulating film formed by a chemical vapor deposition method. The buried insulating layer 301 may include, for example, a silicon oxide film, a silicon nitride film, a silicon oxynitride film, and/or a low dielectric constant insulating film.

The back gate electrode BG, the word-line WL1 and WL2, and the active pattern AP1 and AP2 may be formed on the first sub-substrate 120 and the buried insulating layer 122. Afterwards, the contact pattern BC, the landing pad LP, the contact landing pad C_LP, and the data storage pattern DSP may be formed on the active patterns AP1 and AP2. Subsequently, the first cell contact structure 310, the first lower via V1_L, the second lower via V2_L, the third lower via V3_L, and the second bonding pad BP2 may be formed.

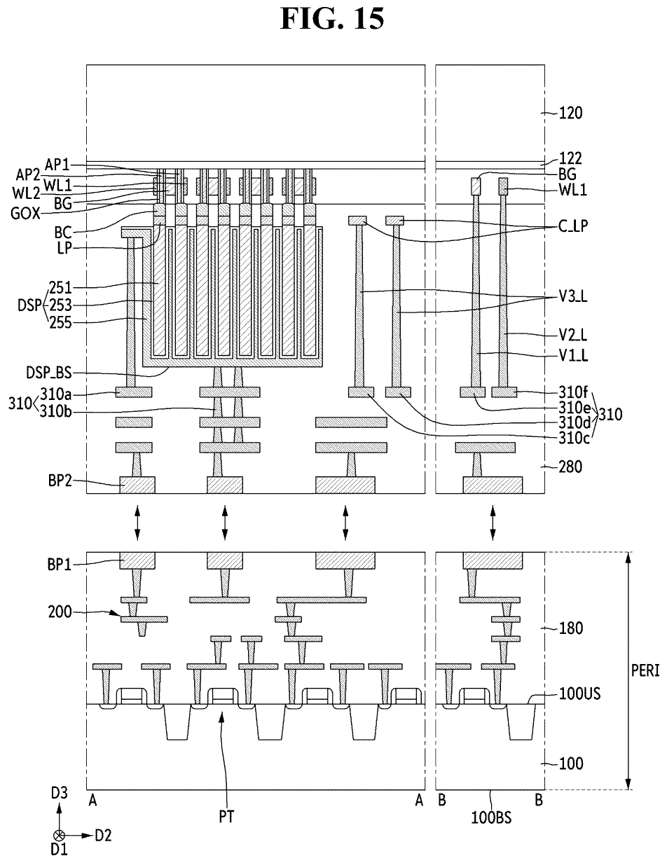

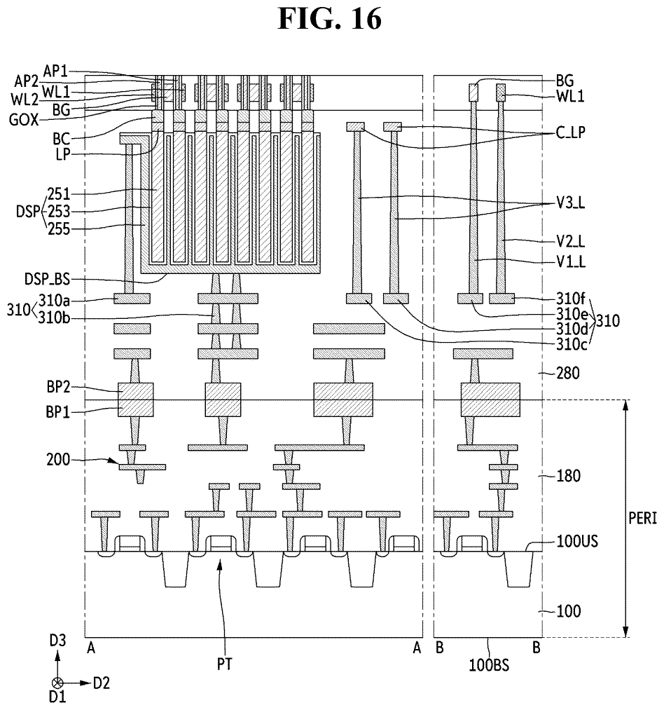

Referring to FIG. 15 and FIG. 16, the peripheral circuit structure PERI including the peripheral circuit substrate 100, the peripheral circuit element PT, the peripheral circuit contact structure 200, and the first bonding pad BP1 may be provided. The resulting structure shown in FIG. 14 is turned upside down so that the first sub-substrate 120 faces upwardly, and then, the second bonding pad BP2 is bonded to the first bonding pad BP1.

Subsequently, the first sub-substrate 120 and the buried insulating layer 122 are removed. Removing the first sub-substrate 120 may include exposing the buried insulating layer 122 by sequentially performing a grinding process and a wet etching process.

Subsequently, the buried insulating layer 122 may be removed to expose the first active pattern AP1 and the second active pattern AP2.

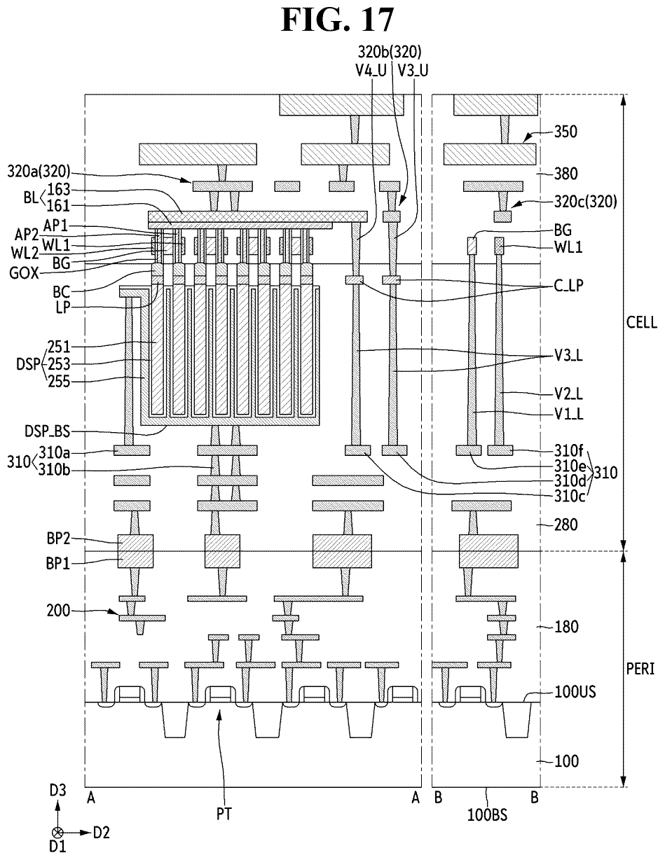

Referring to FIG. 17, the bit-line BL may be formed on the first active pattern AP1 and the second active pattern AP2, and the third upper via V3_U and fourth upper via V4_U may be formed. Subsequently, the second cell contact structure 320 may be formed on the bit-line BL and the third upper via V3_U. Subsequently, the upper wiring structure 350 may be formed on the second cell contact structure 320.

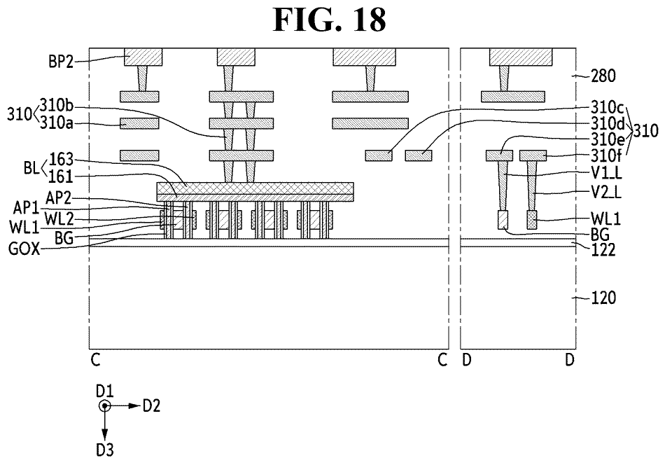

FIGS. 18 to 21 are diagrams for illustrating a semiconductor memory device manufacturing method according to some embodiments of the present disclosure. FIGS. 18 to 21 are diagrams for illustrating the method for manufacturing the semiconductor memory device as shown in FIG. 9. FIGS. 18 to 21 are cross-sectional views taken along lines C-C and D-D of FIG. 8. For convenience of description, contents duplicate with what have been set forth above using FIGS. 1 to 17 are briefly described or the descriptions thereof are omitted.

Referring to FIG. 18, the first sub-substrate 120 and the buried insulating layer 122 may be provided. The back gate electrode BG, the word-line WL1 and WL2, and the active pattern AP1 and AP2 may be formed on the first sub-substrate 120 and the buried insulating layer 122. Subsequently, the bit-line BL may be formed on the active pattern AP1 and AP2. Subsequently, the first lower via V1_L may be formed on the back gate electrode BG, and the second lower via V2_L may be formed on the first word-line WL1. Subsequently, the first cell contact structure 310 may be formed on the bit-line BL, the first lower via V1_L, and the second lower via V2_L. Subsequently, the second bonding pad BP2 may be formed on the first cell contact structure 310.

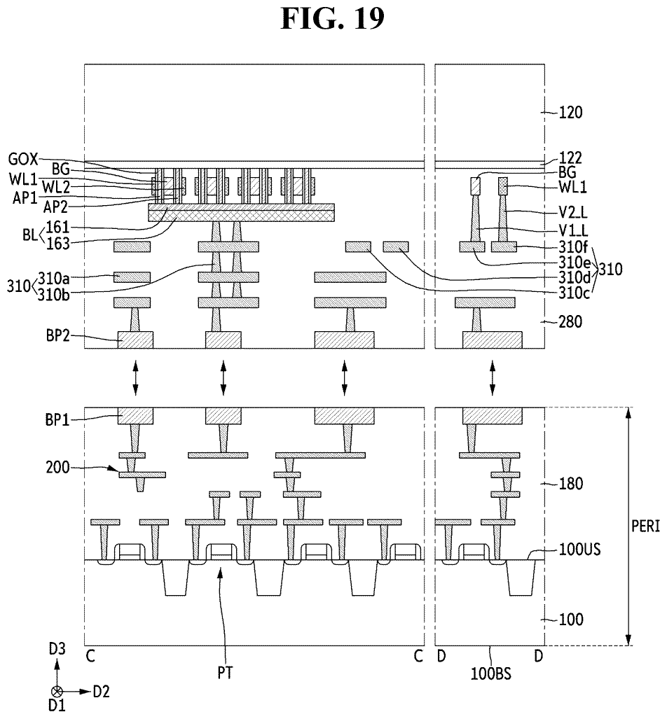

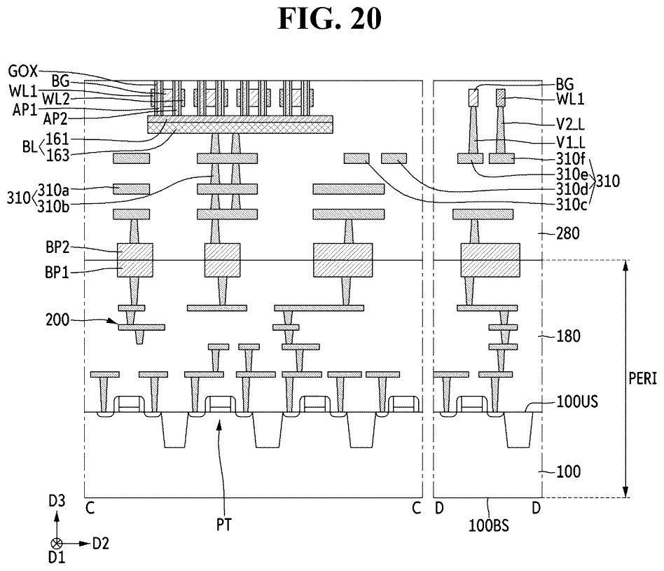

Referring to FIG. 19 and FIG. 20, the peripheral circuit structure PERI including the peripheral circuit substrate 100, the peripheral circuit element PT, the peripheral circuit contact structure 200, and the second bonding pad BP2 may be provided. The resulting structure as shown in FIG. 18 is turned upside down so that the first sub-substrate 120 faces upwardly, and the second bonding pad BP2 is bonded to the first bonding pad BP1.

Subsequently, the first sub-substrate 120 and the buried insulating layer 122 are removed. The first sub-substrate 120 and the buried insulating layer 122 may be removed such that the first active pattern AP1 and the second active pattern AP2 may be exposed.

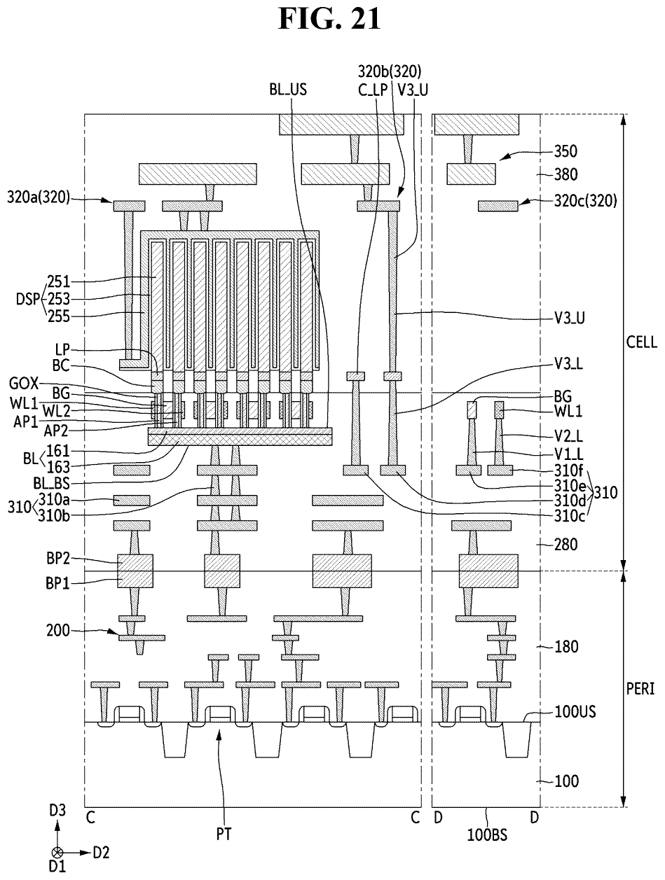

Referring to FIG. 21, the contact pattern BC, the landing pad LP, the contact landing pad C_LP, and the data storage pattern DSP may be formed on the first active pattern AP1 and the second active pattern AP2. Subsequently, the third upper via V3_U may be formed on the contact landing pad C_LP. Alternatively, as shown in FIG. 13, the first upper via V1_U and the second upper via V2_U may be formed on the back gate electrode BG and the first word-line WL1, respectively.

Subsequently, the second cell contact structure 320 and the upper wiring structure 350 may be formed on the data storage pattern DSP.

When manufacturing the semiconductor memory device including the vertical channel transistor, a hybrid bonding process may be performed. When the hybrid bonding process is performed, a trim process may be involved. Thus, when the hybrid bonding process is performed multiple times, a process yield may be lowered.

However, in the manufacturing process of the semiconductor memory device according to some embodiments of the present disclosure, the hybrid bonding process may be performed once. As shown in FIGS. 14 to 17, the data storage pattern DSP may be formed first on the back gate electrode BG, the active pattern AP1 and AP2, and the word-line WL1 and WL2. Subsequently, the first lower via, the second lower via V2_L, the third lower via V3_L, the first cell contact structure 310, and the second bonding pad BP2 may be formed. Afterwards, the resulting structure is turned upside down and bonded to the peripheral circuit structure PERI, and the bit-line BL, the third upper via V3_U, the fourth upper via V4_U, the second cell contact structure 320, and the upper wiring structure 350 may be formed. Alternatively, as shown in FIGS. 18 to 21, the bit-line BL may be formed first on the back gate electrode BG, the active pattern AP1 and AP2, and the word-line WL1 and WL2. Subsequently, the first lower via, the second lower via V2_L, the first cell contact structure 310, and the second bonding pad BP2 may be formed. Afterwards, the resulting structure is turned upside down and bonded to the peripheral circuit structure PERI, and then, the contact pattern BC, the landing pad LP, the contact landing pad C_LP, the data storage pattern DSP, the third upper via V3_U, the second cell contact structure 320 and the upper wiring structure 350 may be formed.

Therefore, the semiconductor memory device according to some embodiments of the present disclosure may be manufactured by performing the hybrid bonding process once. Because the hybrid bonding process is performed only once, the yield of the semiconductor manufacturing process may be improved.

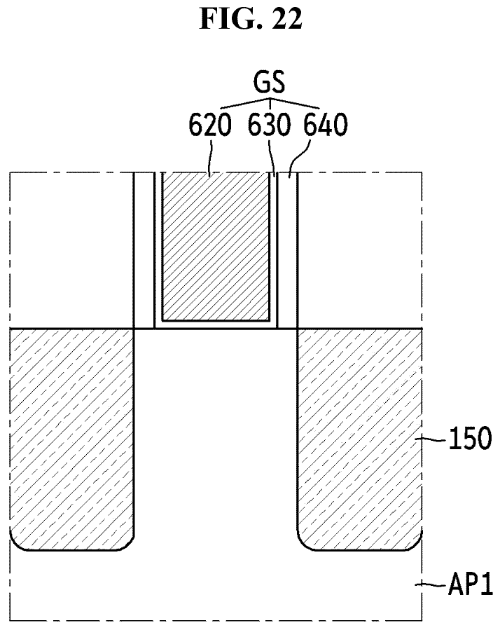

FIGS. 22 to 24 are diagrams showing a peripheral circuit element according to some embodiments.

Referring to FIGS. 22 to 24, the peripheral circuit element PT of the semiconductor memory device according to some embodiments of the present disclosure may include a fin-type transistor (FinFET), a transistor including a nanowire or nanosheet, MBCFETTM™ (Multi-Bridge Channel Field Effect Transistor) and BCAT (Buried Channel Array Transistor) in addition to a planar transistor.

Referring to FIG. 22, the peripheral circuit element PT may be a fin-type transistor. For example, the peripheral circuit element PT may include an active pattern AP1, a source/drain pattern 150, and a gate structure GS.

The active pattern AP1 may be a fin-type pattern. Although not shown, the active pattern AP1 may protrude from the peripheral circuit substrate 100. The active pattern AP1 may be a portion of the peripheral circuit substrate 100 or may include an epitaxial layer grown from the peripheral circuit substrate 100. The active pattern AP1 may include, for example, silicon or germanium which is an elemental semiconductor material. Furthermore, the active pattern AP1 may include a compound semiconductor, for example, a group IV-IV compound semiconductor or a group III-V compound semiconductor. The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

The source/drain pattern 150 may be formed on the active pattern AP1. The source/drain pattern 150 may be connected to the active pattern AP1. The source/drain pattern 150 may include an epitaxial pattern. The source/drain pattern 150 may include a semiconductor material. The source/drain pattern 150 may be included in a source/drain of a transistor using the active pattern AP1 as a channel area.

The gate structure GS may be disposed on the active pattern AP1. The gate structure GS may include a gate electrode 620, a gate insulating film 630, and a gate spacer 640.

The gate electrode 620 may be disposed on the active pattern AP1. For example, the gate electrode 620 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. The present disclosure is not limited thereto. The conductive metal oxide and the conductive metal oxynitride may include oxidized products of the above-mentioned materials. The present disclosure is not limited thereto. The gate electrode 620 may be disposed on each of both opposing sides of the source/drain pattern 150. The gate electrode 620 may be used as a gate of a transistor.

The gate spacer 640 may be disposed on a sidewall of the gate electrode 620. The gate spacer 640 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. The present disclosure is not limited thereto.

The gate insulating film 630 may extend along a sidewall and a bottom surface of the gate electrode 620. The gate insulating film 630 may be formed on the active pattern AP1. The gate insulating film 630 may be formed between the gate electrode 620 and the gate spacer 640. The gate insulating film 630 may include silicon oxide, silicon oxynitride, silicon nitride, or a high dielectric constant material with a higher dielectric constant than that of silicon oxide. The high dielectric constant (high-k) material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

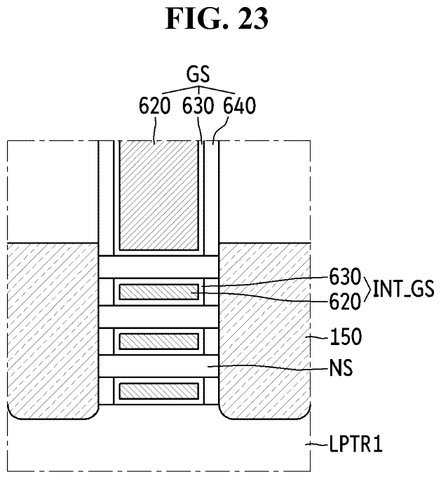

Referring to FIG. 23, the peripheral circuit element PT may be a Multi-Bridge Channel Field Effect Transistor (MBCFET™). For example, the peripheral circuit element PT may include a lower pattern LPTR1, a sheet pattern NS, an inner gate structure GS, a source/drain pattern 150, and a gate structure GS.

The lower pattern LPTR1 may protrude from the peripheral circuit substrate 100. The sheet pattern NS may be disposed on the lower pattern LPTR1. The lower pattern LPTR1 may be formed by etching a portion of the peripheral circuit substrate 100 or may include an epitaxial layer grown from the peripheral circuit substrate 100. The lower pattern LPTR1 may include silicon or germanium as an elemental semiconductor material. Alternatively, the lower pattern LPTR1 may include a compound semiconductor, for example, a group IV-IV compound semiconductor or a group III-V compound semiconductor.

The sheet pattern NS may include one of the elemental semiconductor material such as silicon or germanium, the group IV-IV compound semiconductor, or the group III-V compound semiconductor. Each sheet pattern NS may include the same material as that of the lower pattern LPTR1, or may include a material different from that of the lower pattern LPTR1.

The source/drain pattern 150 may be formed on the lower pattern LPTR1. The description about the source/drain pattern 150 may be substantially the same as the description as set forth above using FIG. 22.

An inner gate structure INT_GS may be disposed between the sheet patterns NS. The inner gate structure INT_GS may be disposed between the sheet pattern NS and the lower pattern LPTR1.

The inner gate structure INT_GS may include a gate electrode 620 and a gate insulating film 630. The descriptions about the gate electrode 620 and the gate insulating film 630 may be substantially the same as the descriptions as set forth above using FIG. 22.

The gate structure GS may be disposed on the sheet pattern NS. The description about the gate structure GS may be substantially the same as the description as set forth above using FIG. 22.

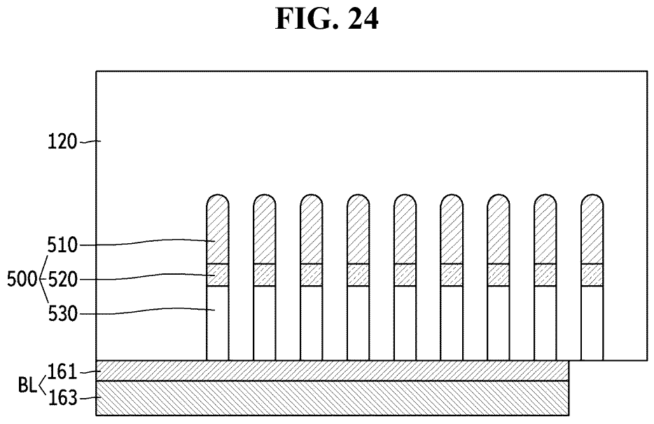

Referring to FIG. 24, the peripheral circuit element PT may be a Buried Channel Array Transistor (BCAT). For example, the peripheral circuit element PT may have a first sub-substrate 120 including a cell gate structure 500 disposed on the bit-line BL.

The cell gate structure 500 may include a cell gate electrode 510, a cell gate capping conductive film 520, and a cell gate capping pattern 530. The cell gate structure 500 may be a buried gate structure buried in the first sub-substrate 120.

The cell gate electrode 510 may include a conductive material, and may include at least one of doped polysilicon, conductive metal nitride, conductive metal silicon nitride, metal carbonitride, conductive metal silicide, conductive metal oxide, two-dimensional materials, metals, and metal alloys. The cell gate capping conductive film 520 may include, for example, polysilicon or polysilicon-germanium. However, embodiments of the present disclosure are not limited thereto. The cell gate capping pattern 530 may include at least one of silicon nitride (SiN), silicon oxynitride (SiON), silicon carbonitride (SiCN), silicon oxycarbonitride (SiOCN), and combinations thereof.

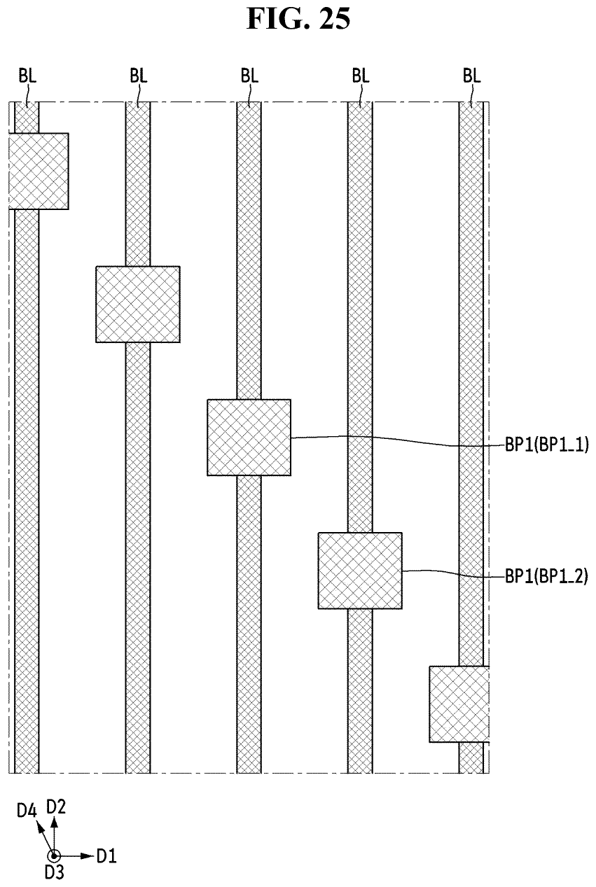

FIGS. 25 to 30 are diagrams for illustrating a shape and/or arrangement of the first bonding pad BP1 according to some embodiments.

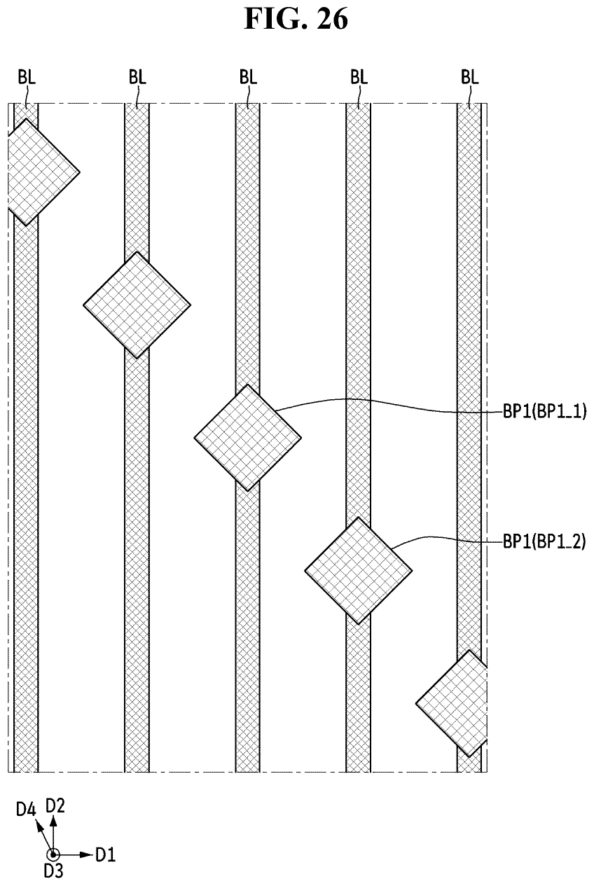

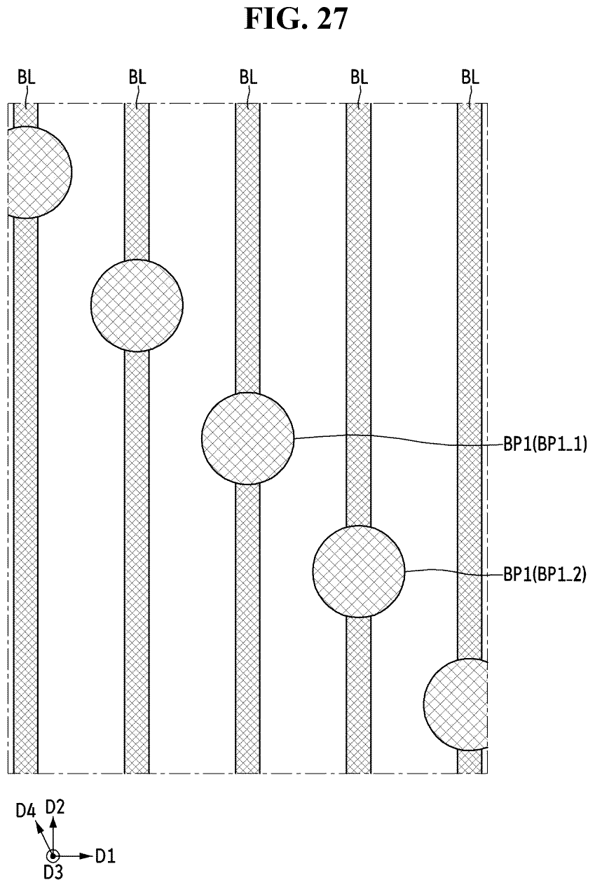

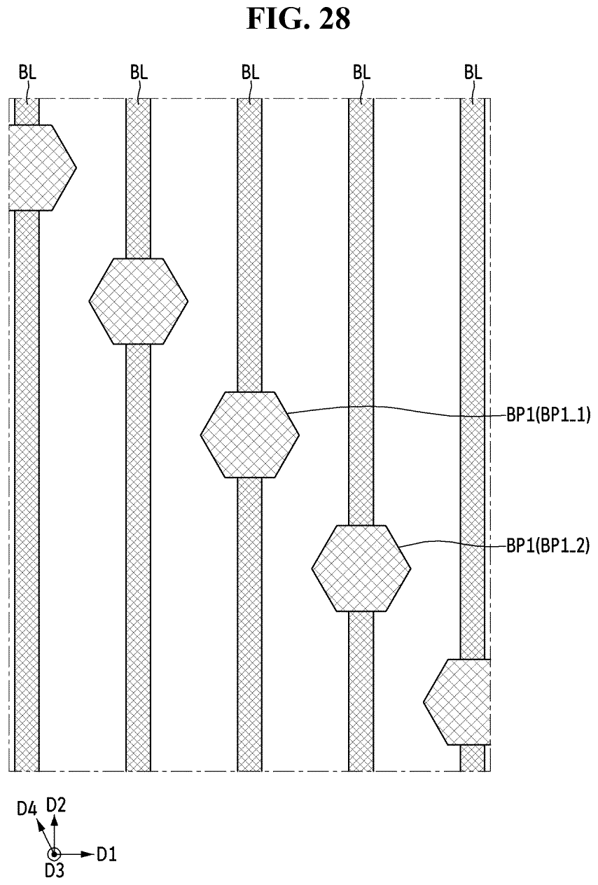

In FIG. 25, in a plan view, the first bonding pad BP1 may have a square shape. In FIG. 26, the first bonding pad BP1 may have a diamond shape. In FIG. 27, in a plan view, the first bonding pad BP1 may have a circular or oval shape. In FIG. 28, in a plan view, the first bonding pad BP1 may have a hexagonal shape. Although not shown, in the plan view, the second bonding pad BP2 may have various shapes such as square, diamond, circle, oval, and hexagon.

In FIGS. 25 to 30, the first bonding pad BP1 may include a first sub-bonding BP1_1 and a second sub-bonding pad BP1_2 immediately adjacent to each other. The first sub-bonding BP1_1 and the second sub-bonding pad BP1_2 may be arranged in a fourth direction D4.

The fourth direction D4 may intersect the first direction D1 and the second direction D2. The fourth direction D4 may be parallel to the upper surface of the peripheral circuit substrate 100.

In FIGS. 25 to 28, the first bonding pads BP1 may be arranged continuously along the fourth direction D4.

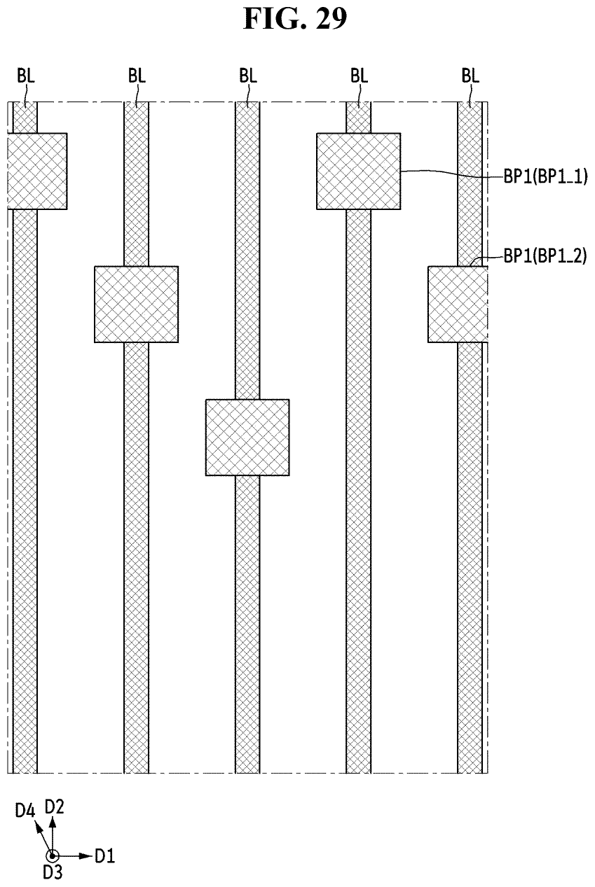

In FIG. 29, the first bonding pad BP1 may include a plurality of pad groups, each including three or more first bonding pads BP1. The first bonding pads BP1 included in each pad group may be continuously arranged along the fourth direction D4. The pad groups may be arranged along the first direction D1.

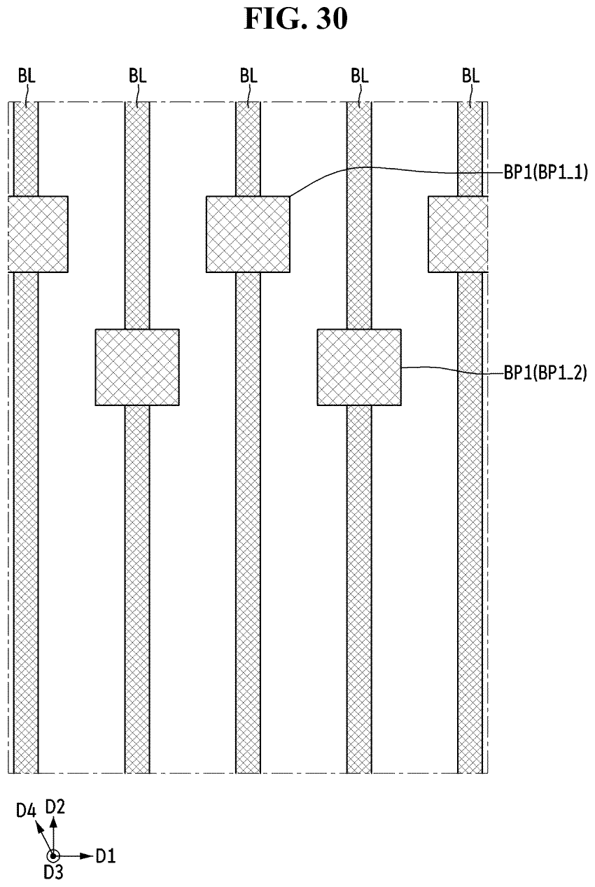

In FIG. 30, the first bonding pads BP1 may be arranged in a zigzag pattern along the first direction D1 and the fourth direction D4.

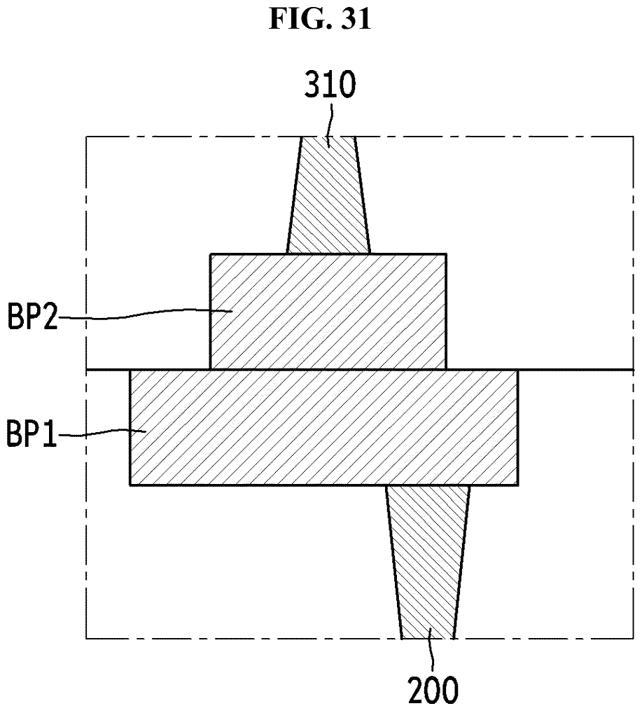

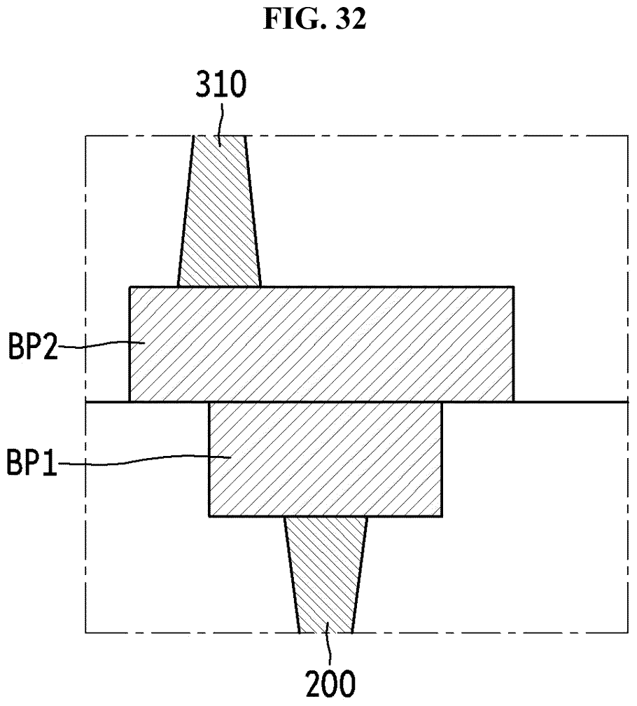

FIG. 31 and FIG. 32 are diagrams for illustrating an arrangement of the first bonding pad and the second bonding pad according to some embodiments.

Referring to FIG. 31 and FIG. 32, sizes of the first bonding pad BP1 and the second bonding pad BP2 may be different from each other. For example, as shown in FIG. 31, the size of the first bonding pad BP1 may be larger than the size of the second bonding pad BP2. A horizontal width of the first bonding pad BP1 may be larger than a horizontal width of the second bonding pad BP2. Conversely, as shown in FIG. 32, the size of the second bonding pad BP2 may be larger than the size of the first bonding pad BP1. The horizontal width of the second bonding pad BP2 may be larger than the horizontal width of the first bonding pad BP1.

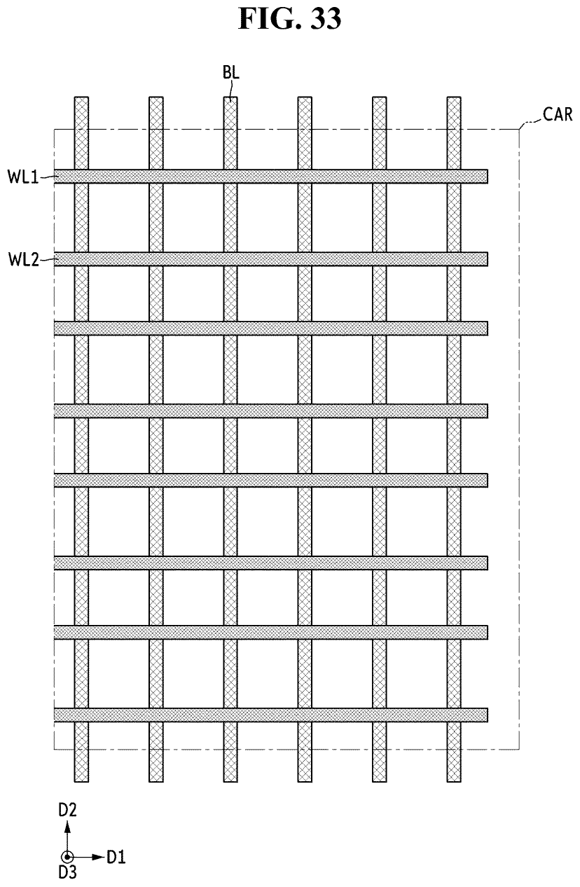

FIGS. 33 to 35 are diagrams for illustrating an arrangement of the bit line, the word-line, the shielding conductive line, and the back gate electrode according to some embodiments.

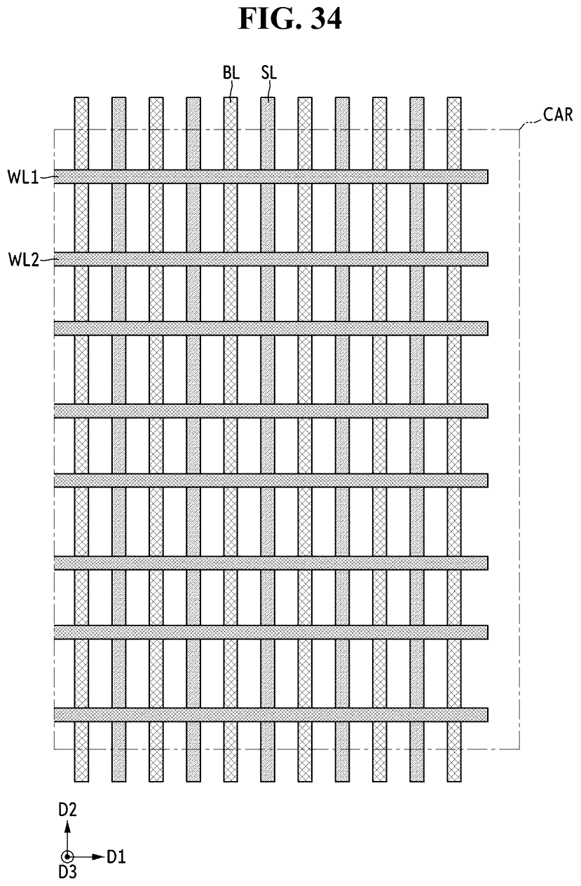

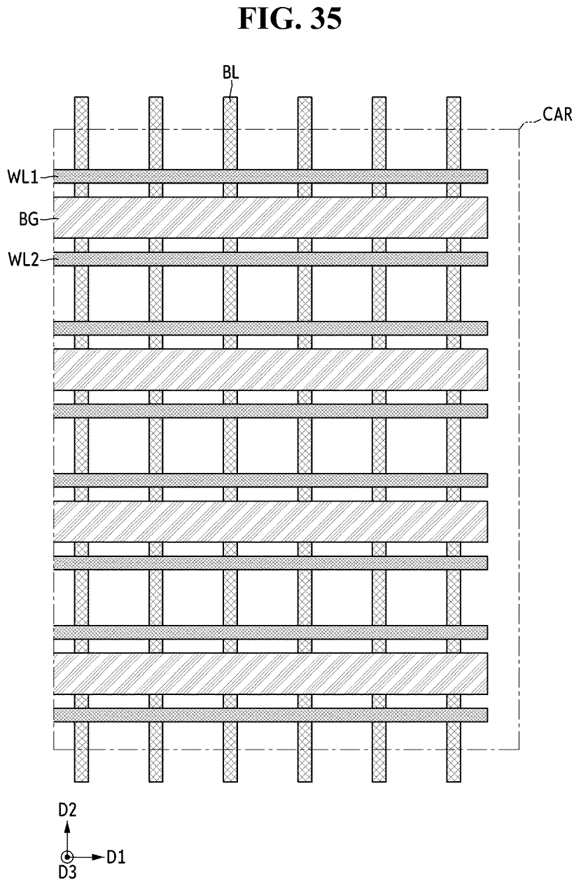

Unlike what is shown in FIG. 2, the semiconductor memory device according to some embodiments of the present disclosure may include only the bit-line BL and the word-line WL1 and WL2, as shown in FIG. 33. Alternatively, in some embodiments, the semiconductor memory device may include only the bit-line BL, the shielding conductive line SL, and the word-line WL1 and WL2, as shown in FIG. 34. Alternatively, in some embodiments, the semiconductor memory device may include only the bit-line BL, the word-line WL1 and WL2, and the back gate electrode BG, as shown in FIG. 35.

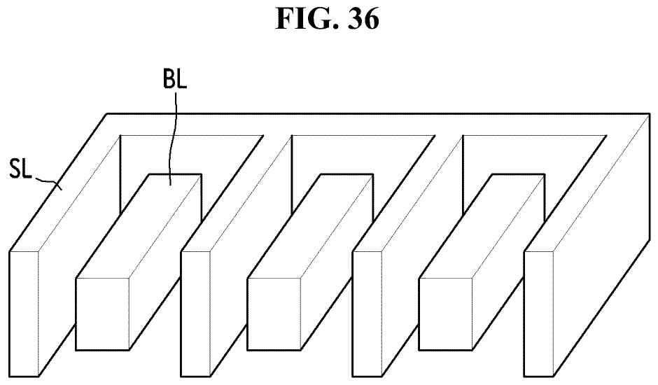

FIGS. 36 to 55 are diagrams for illustrating the arrangement of the bit-line, the shielding conductive line, the bit-line contact, and the shielding conductive line contact according to some embodiments.

In FIGS. 36 to 42, the semiconductor memory device according to some embodiments may include the bit-line BL, the shielding conductive line SL, a bit-line contact BL_CNT, and the shielding conductive line contact SL_CNT. The shielding conductive line SL may be of a line type. The shielding conductive line SL may be disposed between and around the bit-lines BL. That is, the shielding conductive line SL and the bit-lines BL may be arranged in an interdigitated manner.

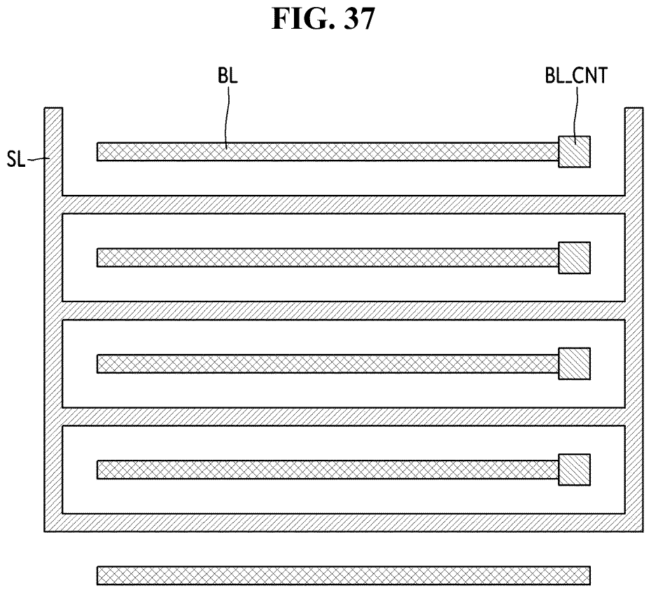

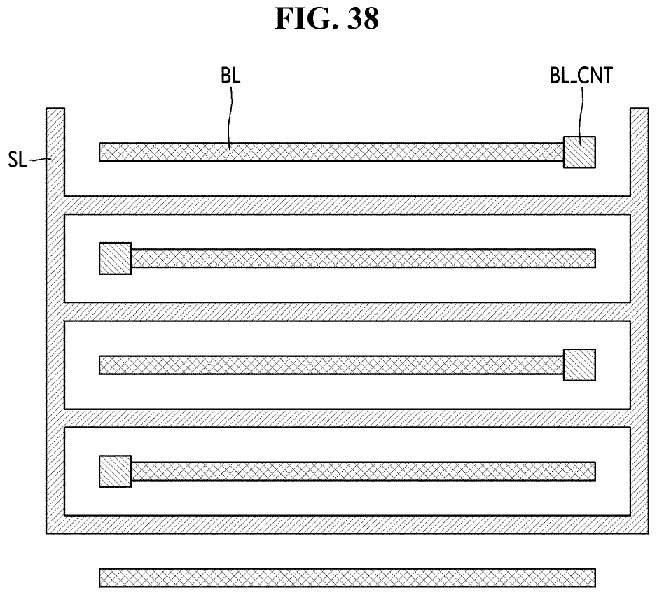

In FIG. 37, the bit-line contact BL_CNT may be disposed at an end of the bit-line BL. The bit-line contact BL_CNT may be electrically connected to the bit-line BL. In FIG. 38, the bit-line contacts BL_CNT may be respectively disposed at both opposing ends of the bit-line BL and may be arranged in a zigzag manner.

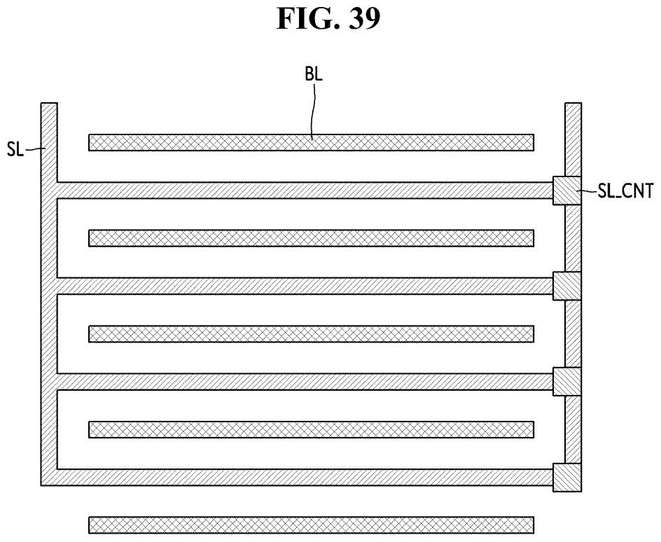

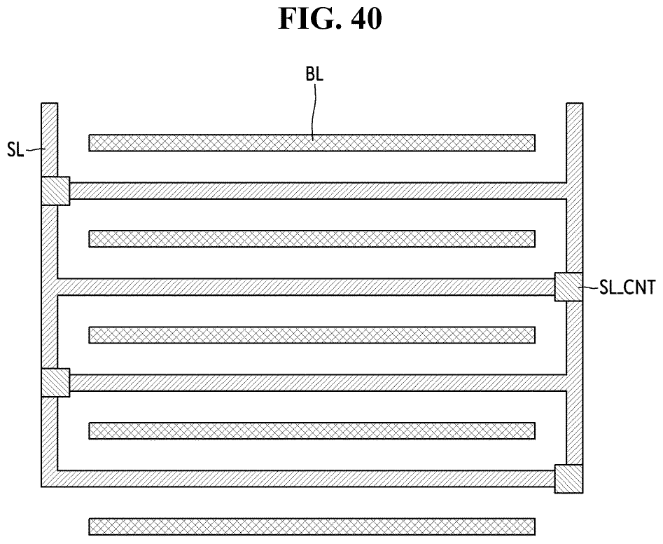

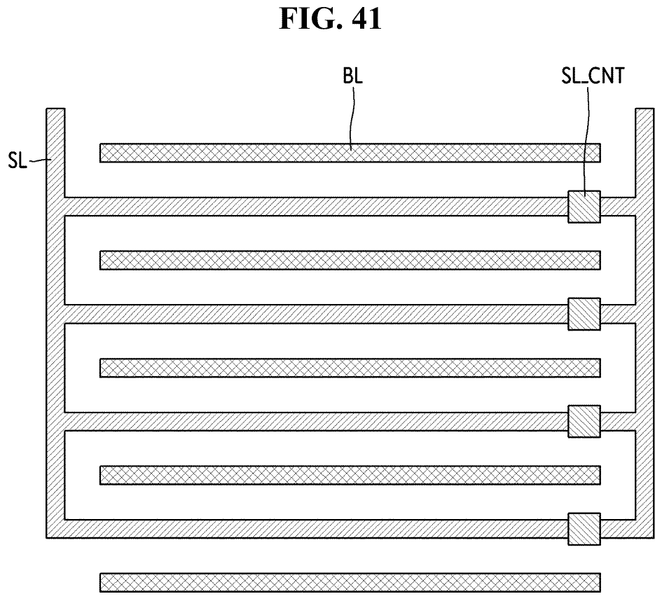

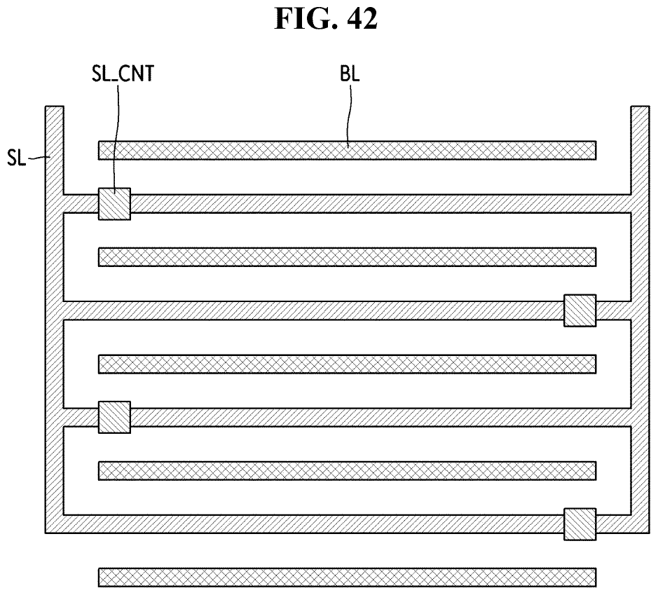

In FIG. 39, the shielding conductive line SL may include a vertical portion and a horizontal portion in the plan view. The shielding conductive line contact SL_CNT may be disposed at a point where the vertical portion and the horizontal portion of the shielding conductive line SL intersect each other. The shielding conductive line contact SL_CNT may be electrically connected to the shielding conductive line SL. In FIG. 40, the shielding conductive line contacts SL_CNT may be disposed at the points where the vertical and horizontal portions of the shielding conductive line SL intersect each other and may be arranged in the zig-zag manner. In FIG. 41 and FIG. 42, the shielding conductive line contact SL_CNT may be arranged in one direction or in the zigzag manner and may be disposed between the bit-lines BL.

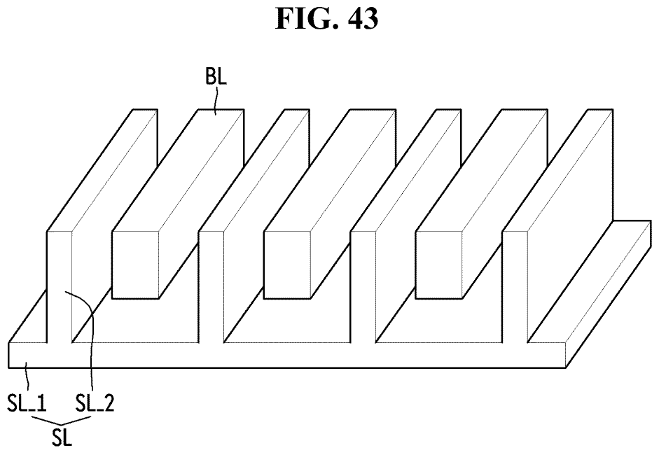

In FIGS. 43 to 52, the semiconductor memory device according to some embodiments may include the bit-line BL, the shielding conductive line SL, the bit-line contact BL_CNT, and the shielding conductive line contact SL_CNT. The shielding conductive line SL may be of a plate type. The shielding conductive line SL may include a first portion SL_1 disposed under the bit-line BL and a second portion SL_2 disposed between the bit-lines BL. The bit-line BL may be disposed on the first portion SL_1 of the shielding conductive line SL. The bit-line BL may overlap, in the vertical direction, with the first portion SL_1 of the shielding conductive line SL. The bit-line BL may overlap the second portion SL_2 of the shielding conductive line SL in the horizontal direction.

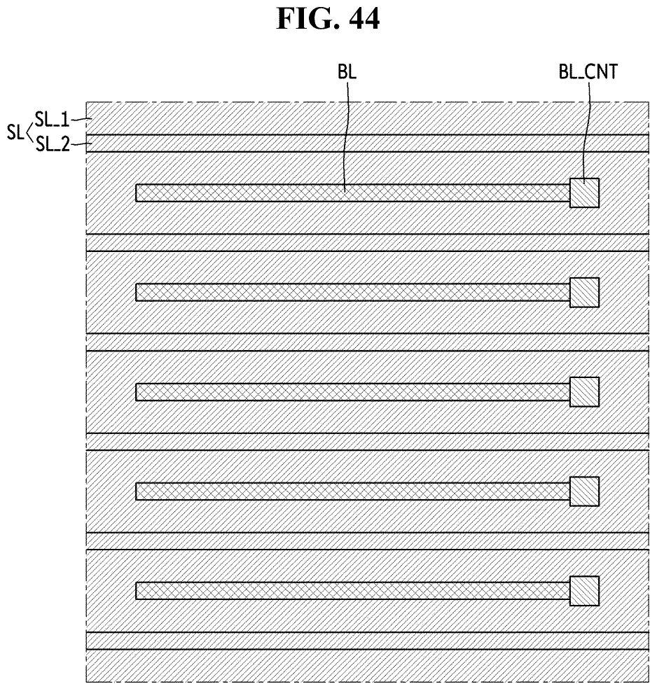

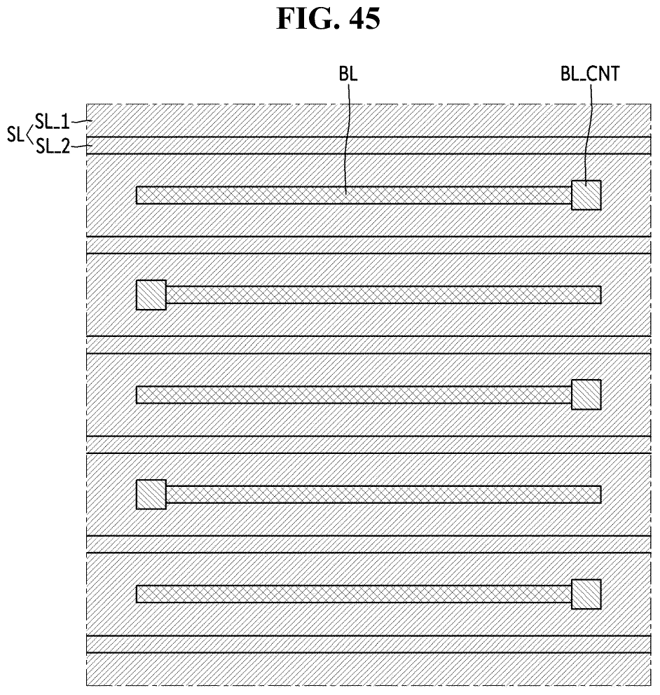

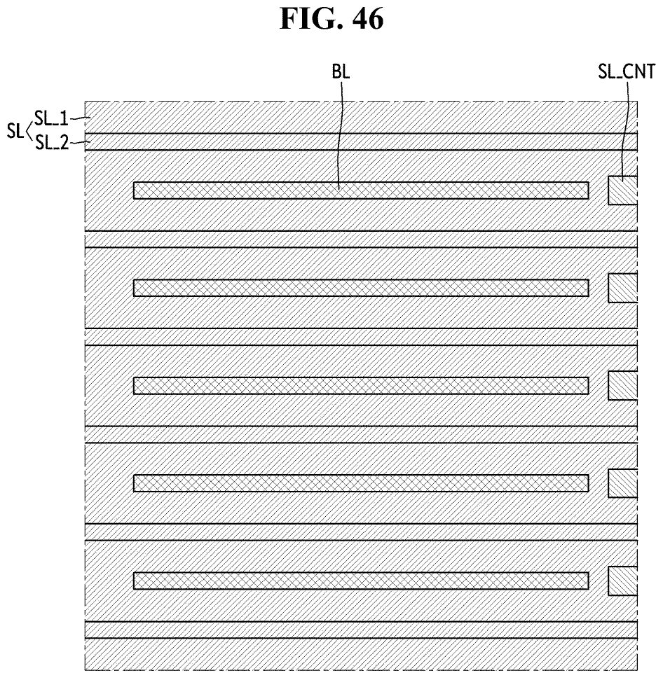

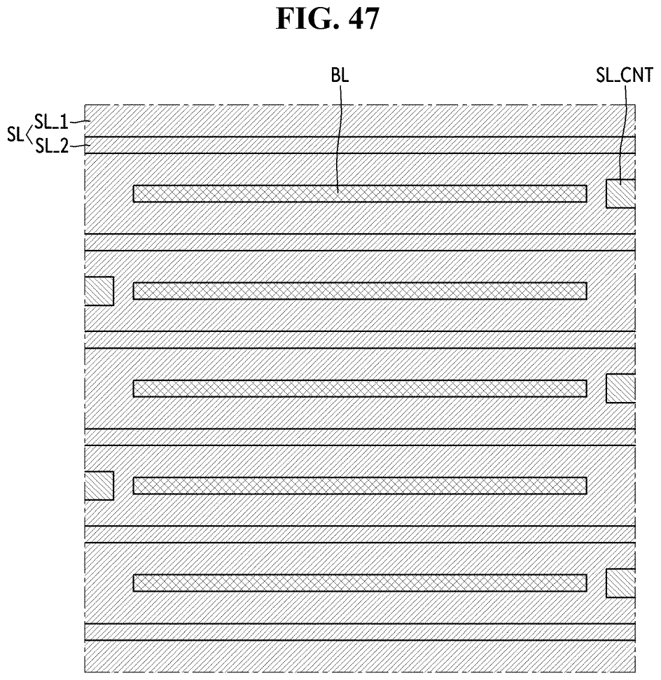

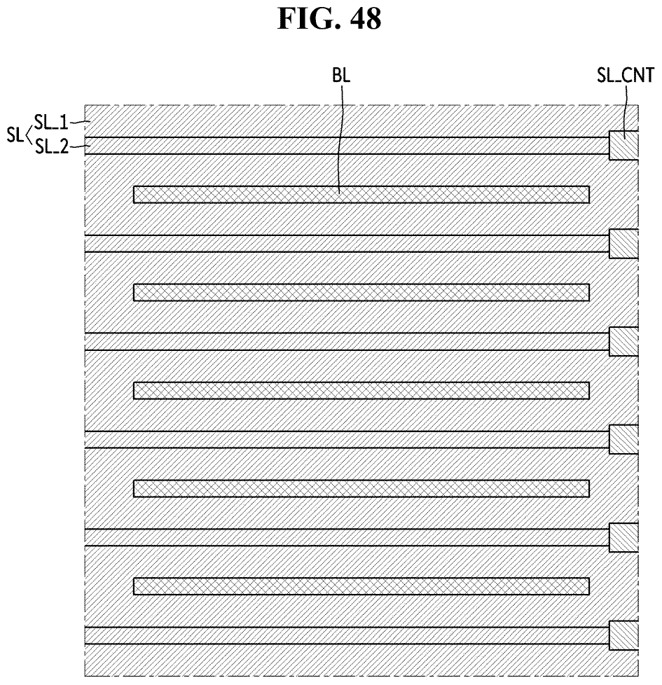

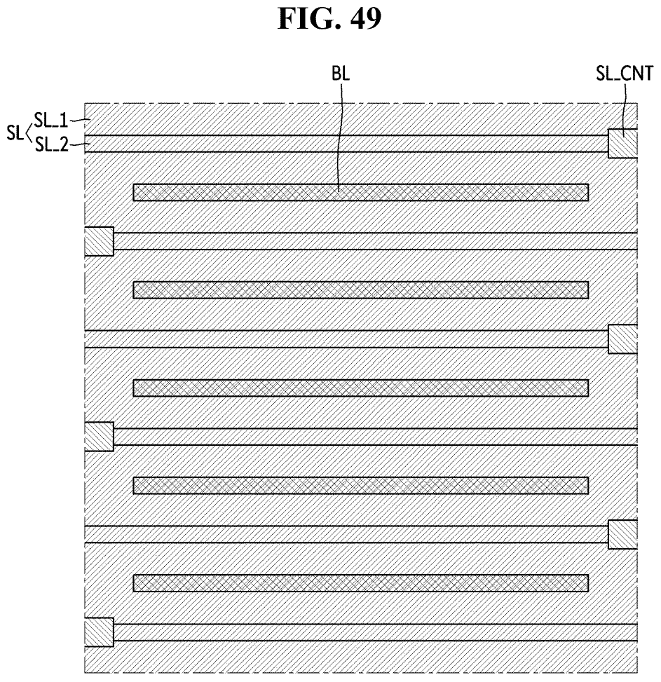

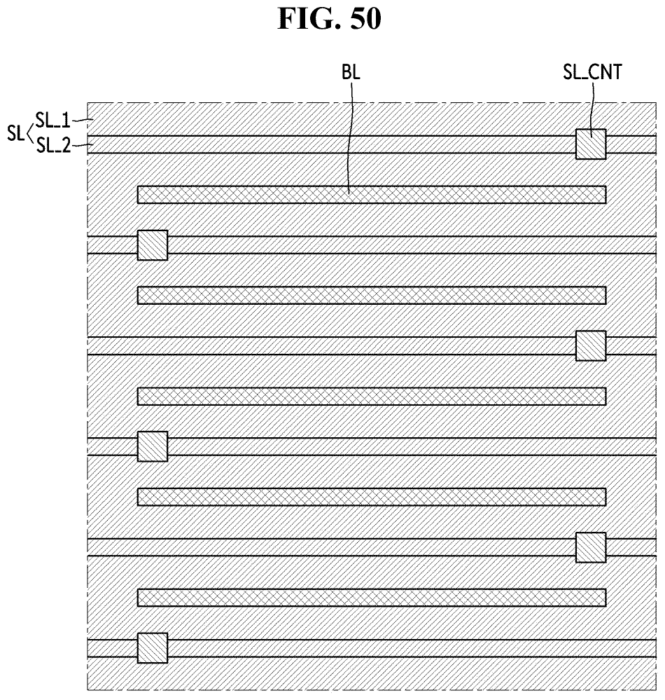

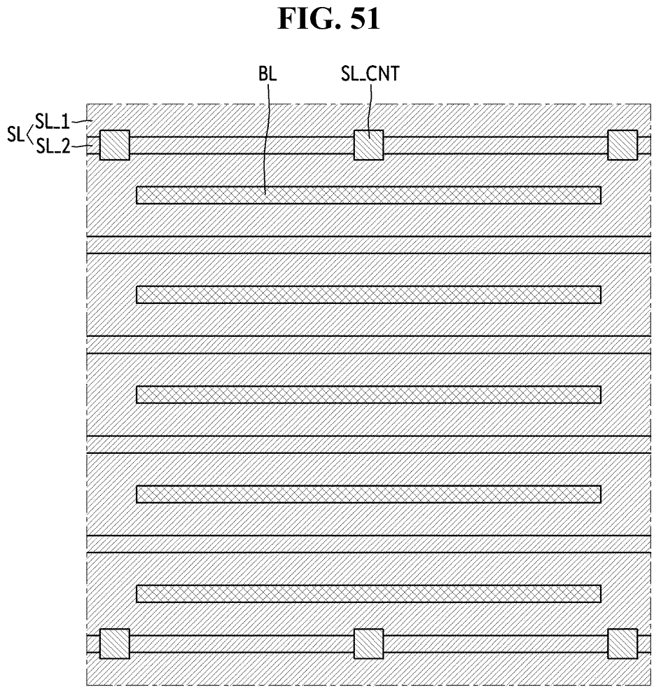

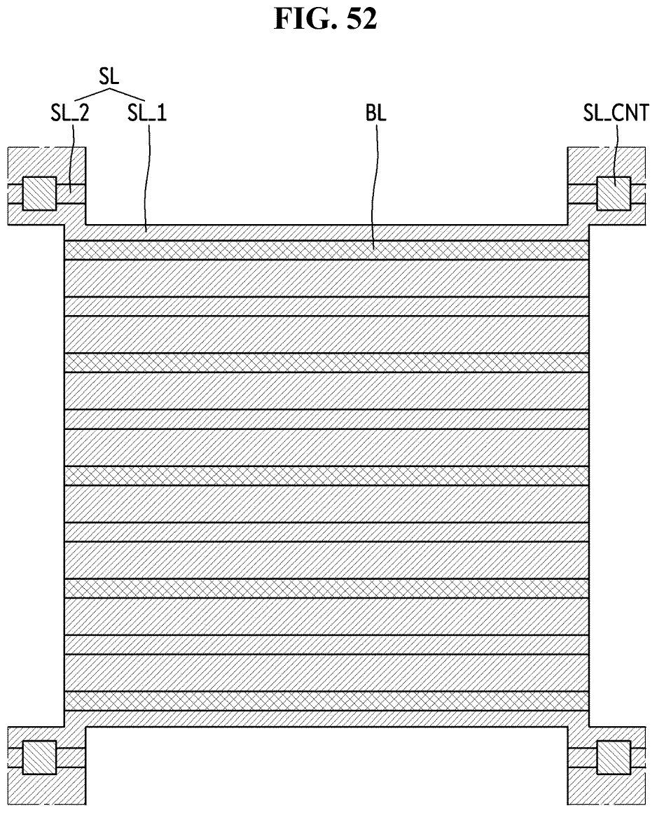

In FIG. 44, the bit-line contact BL_CNT may be disposed at an end of the bit-line BL. In FIG. 45, the bit-line contacts BL_CNT may be respectively disposed at both opposing ends of the bit-line BL and may be arranged in the zigzag manner. In FIG. 46, the shielding conductive line contact SL_CNT may be disposed on the first portion SL_1 of the shielding conductive line SL. The shielding conductive line contact SL_CNT may be disposed at an end of the first portion SL_1, and may be spaced apart from the bit-line BL. In FIG. 47, the shielding conductive line contacts SL_CNT may be respectively disposed on both opposing ends of the first portion SL_1 of the shielding conductive line SL and may be arranged in the zigzag manner. The shielding conductive line contacts SL_CNT may be respectively disposed at both opposing ends of the second portion SL_2, and may be spaced apart from the bit-line BL. In FIG. 48, the shielding conductive line contact SL_CNT may be disposed on the second portion SL_2 of the shielding conductive line SL. The shielding conductive line contact SL_CNT may be disposed at an end of the second portion SL_2. In FIG. 49, the shielding conductive line contact SL_CNT may be respectively disposed on both opposing ends of the second portion SL_2 of the shielding conductive line SL and may be arranged in the zigzag manner. In FIG. 50, the shielding conductive line contacts SL_CNT may be disposed on the second portion SL_2 of the shielding conductive line SL, and may be disposed between the bit-lines BL and may be arranged in the zigzag manner. In FIG. 51, a plurality of shielding conductive line contacts SL_CNT may be disposed in each of some of the second portions SL_2 of the shielding conductive line SL, while the shielding conductive line contact SL_CNT may not be disposed in each of the others of the second portions SL_2. In FIG. 52, an area where the shielding conductive line contact SL_CNT is disposed may be formed by patterning the shielding conductive line SL. The shielding conductive line contact SL_CNT may be disposed on the second portion SL_2 of the shielding conductive line SL in an area formed by patterning the shielding conductive line SL.

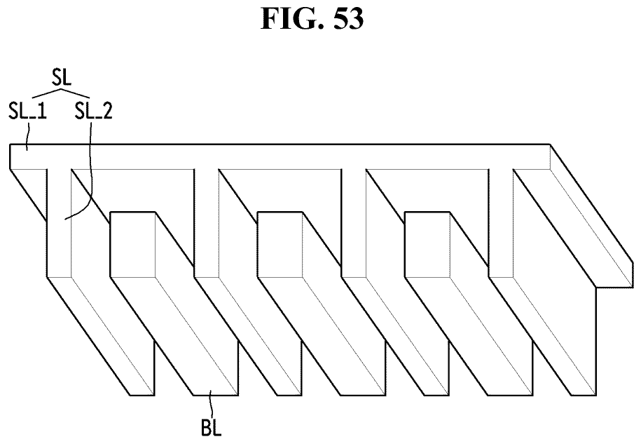

In FIGS. 53 to 55, the semiconductor memory device according to some embodiments may include the bit-line BL, the shielding conductive line SL, and the bit-line contact BL_CNT. The shielding conductive line SL may be of the plate type. The first portion SL_1 of the shielding conductive line SL may be disposed on the bit-line BL. The second portion SL_2 of the shielding conductive line SL may be disposed between the bit-lines BL. The bit-line BL may be disposed under the first portion SL_1 of the shielding conductive line SL.

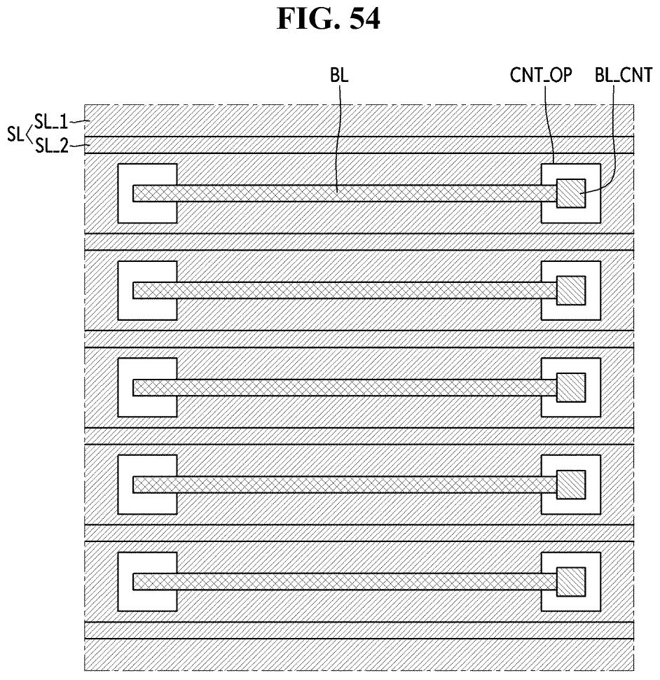

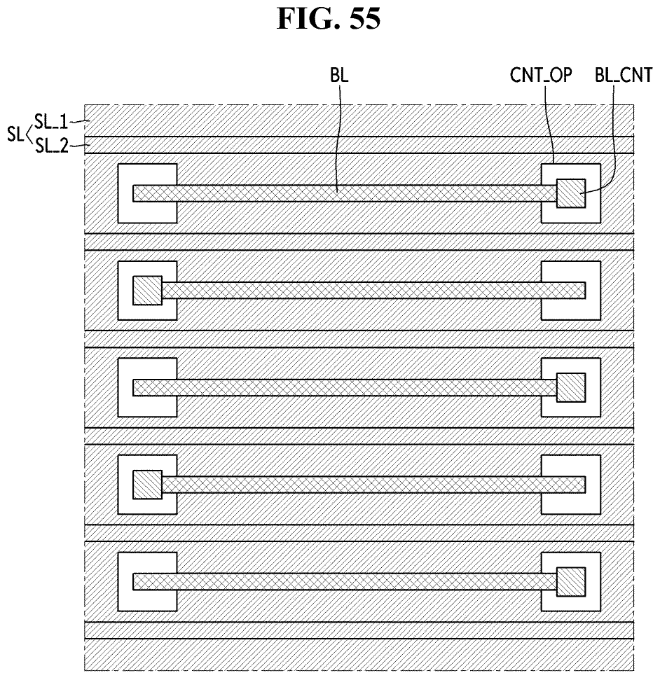

In FIG. 54 and FIG. 55, a portion of the shielding conductive line SL may be patterned at each of both opposing ends of the bit-line BL to form a contact open area BL_CNT. The bit-line contact BL_CNT may be disposed in the contact open area BL_CNT and may be electrically connected to the bit-line BL. The bit-line contact BL_CNT may be disposed at the end of the bit-line BL and in the contact open area BL_CNT. Alternatively, the bit-line contacts BL_CNT may be arranged in the zigzag manner while being respectively disposed at both opposing ends of the bit-line BL and in the contact open areas BL_CNT.

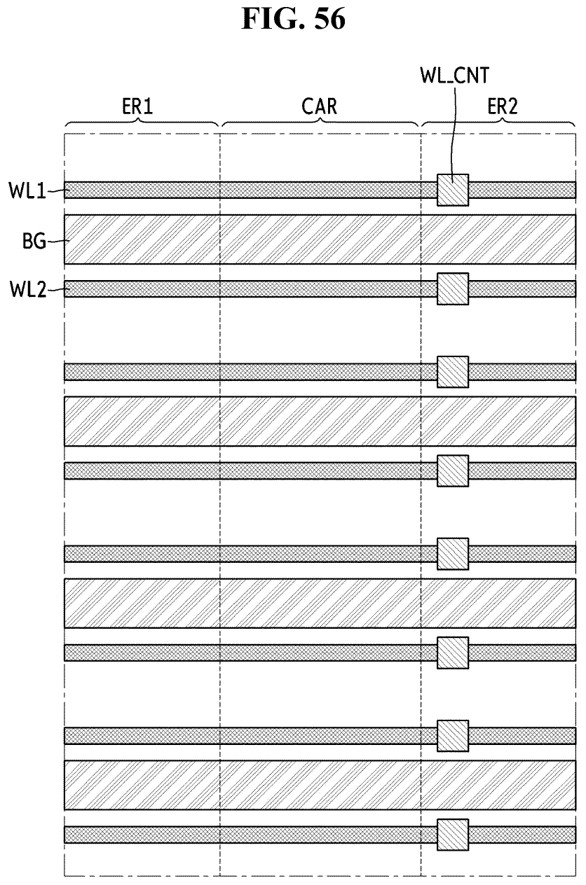

FIGS. 56 to 61 are diagrams for illustrating the arrangement of the word-line, the back gate electrode, the word-line contact, and the back gate contact according to some embodiments. The word-line contact may be electrically connected to the word-line. The back gate contact may be electrically connected to the back gate electrode.

The word-line WL1 and WL2 and the back gate electrode BG may extend from the cell array area CAR to first and second edge areas ER1 and ER2 opposite to each other. The first edge area ER1 and the second edge area ER2 may be included in the cell peripheral circuit area PCR.

In FIG. 56, the word-line contact WL_CNT may be disposed on each of the first word-line WL1 and the second word-line WL2 and in the second edge area ER2. Although not shown, the word-line contact WL_CNT may be disposed on each of the first word-line WL1 and the second word-line WL2 and in the first edge area ER1.

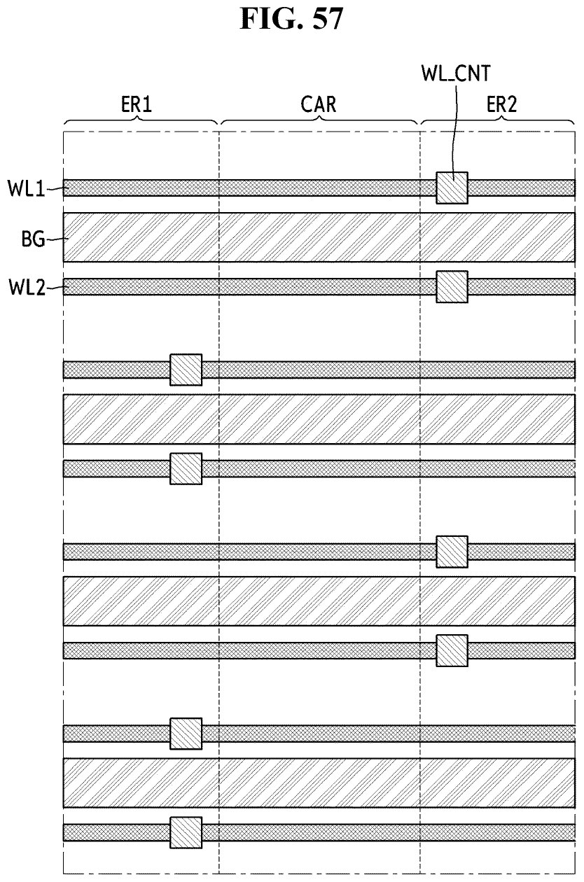

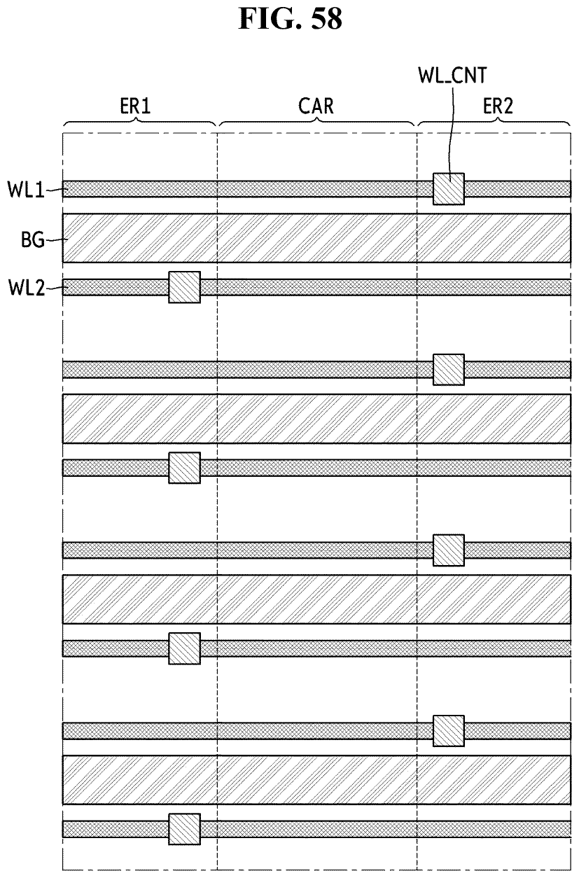

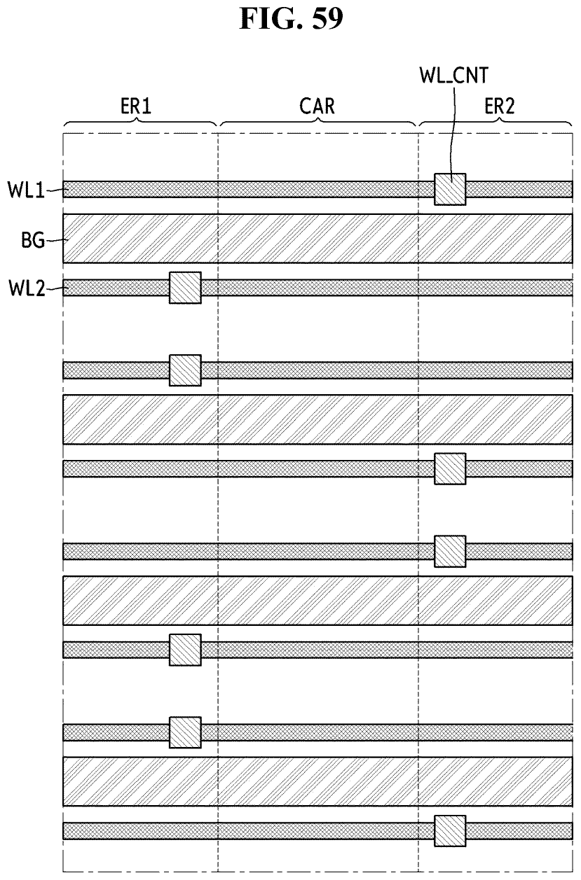

In FIG. 57 and FIG. 59, the word-line contacts WL_CNT may be disposed on the word-lines WL1 and WL2 and in the second edge area ER2 and the first edge area ER1 and may be arranged in a zigzag manner. In FIG. 57, some of the word-line contacts WL_CNT may be disposed on the word-lines WL1 and WL2 and in the second edge area ER2, and the others of the word-line contacts WL_CNT may be disposed on the word-lines WL1 and WL2 adjacent to the word-lines WL1 and WL2 on which some of the word-line contacts WL_CNT are disposed and in the first edge area ER1. In FIG. 58, the word-line contacts WL_CNT may be disposed on the word-lines WL1 and WL2, and in the first edge area ER1 and the second edge area ER2 and may be arranged in the zigzag manner. For example, the word-line contact WL_CNT may be disposed on the first word-line WL1 and in the second edge area ER2, and may be disposed on the second word-line WL2 and in the first edge area ER1. In FIG. 59, in the first edge area ER1, the word-line contact WL_CNT may be disposed on each of the first word-line WL1 and the second word-line WL2 which are disposed between the back gate electrodes BG. Further, in the second edge area ER2, the word-line contact WL_CNT may be disposed on each of the first word-line WL1 and the second word-line WL2 which are disposed between the back gate electrodes BG.

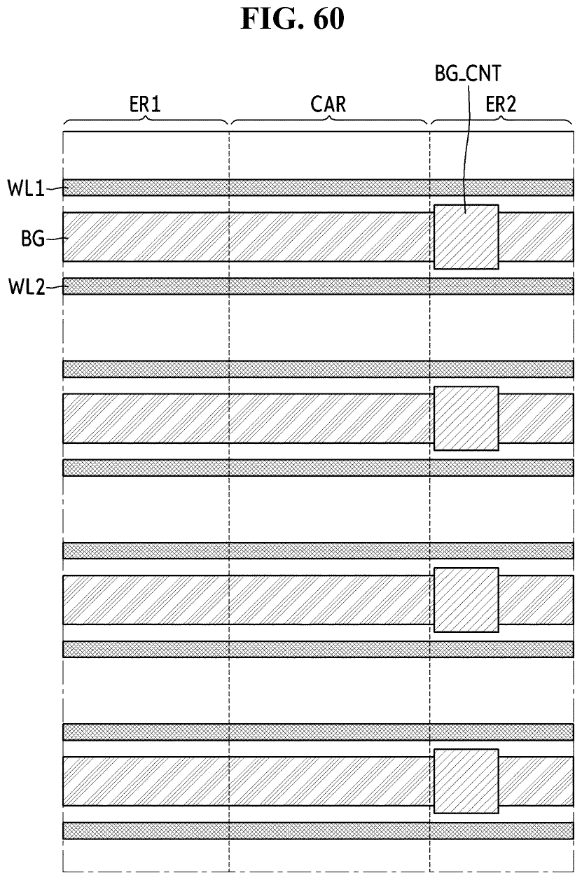

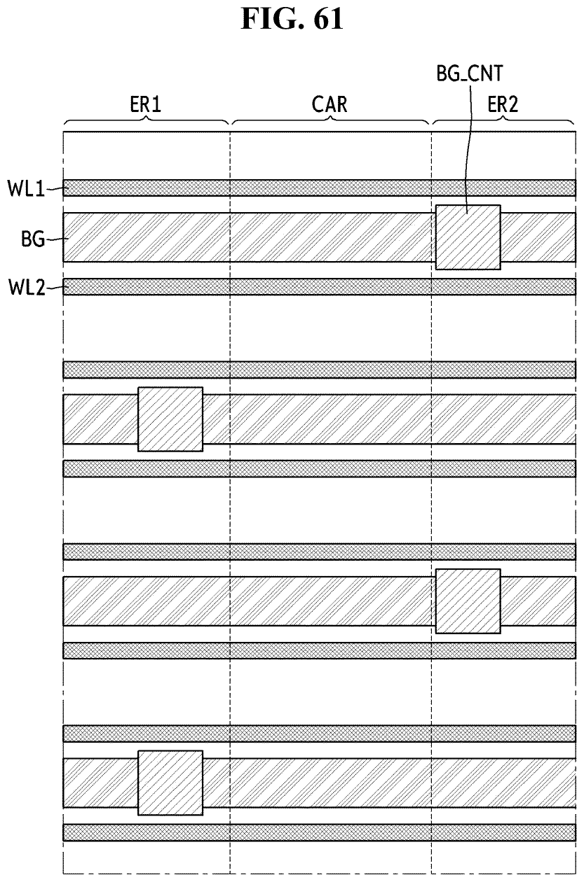

In FIG. 60, the back gate contact BG_CNT may be disposed on the back gate electrode BG and in the second edge area ER2. Alternatively, although not shown, the back gate contact BG_CNT may be disposed on the back gate electrode BG and in the first edge area ER1. In FIG. 61, the back gate contacts BG_CNT may be respectively disposed on the back gate electrodes BG and in the first edge area ER1 and the second edge area ER2 and may be arranged in the zigzag manner.

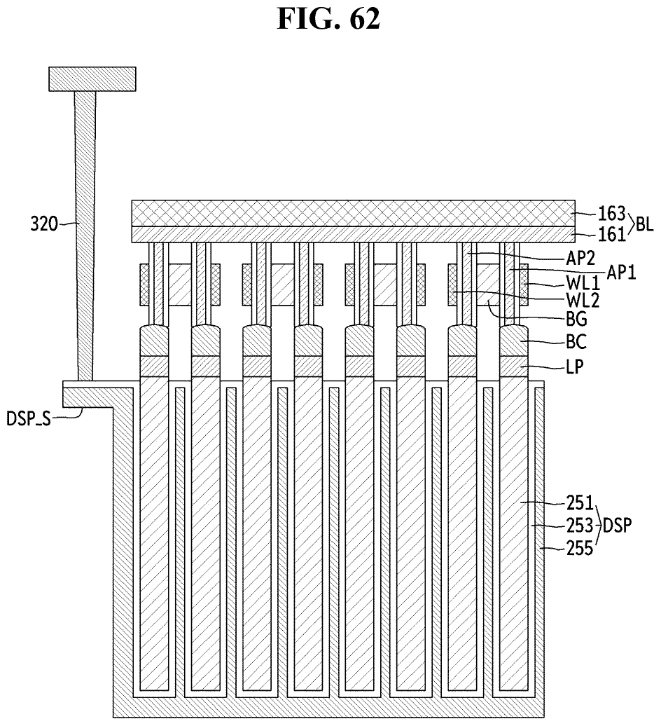

FIGS. 62 to 65 are diagrams for illustrating an arrangement of the data storage pattern and the second cell contact structure according to some embodiments. A surface of the data storage pattern DSP where the data storage pattern DSP may be connected to the landing pad LP may be a back surface of the data storage pattern DSP, and the opposite surface thereto may be a front surface.

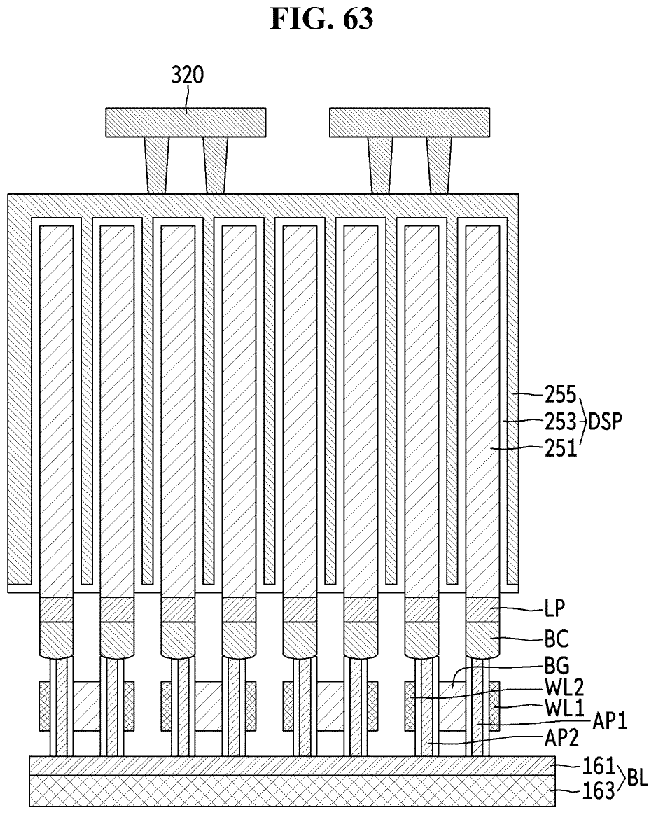

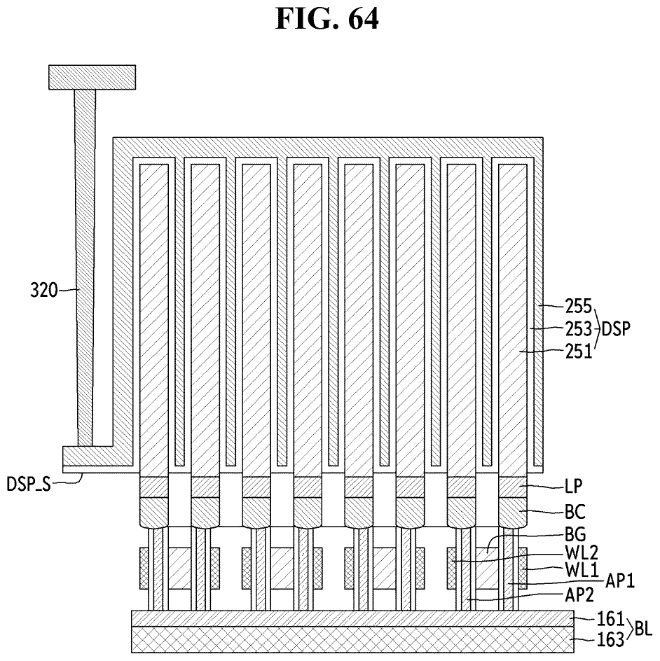

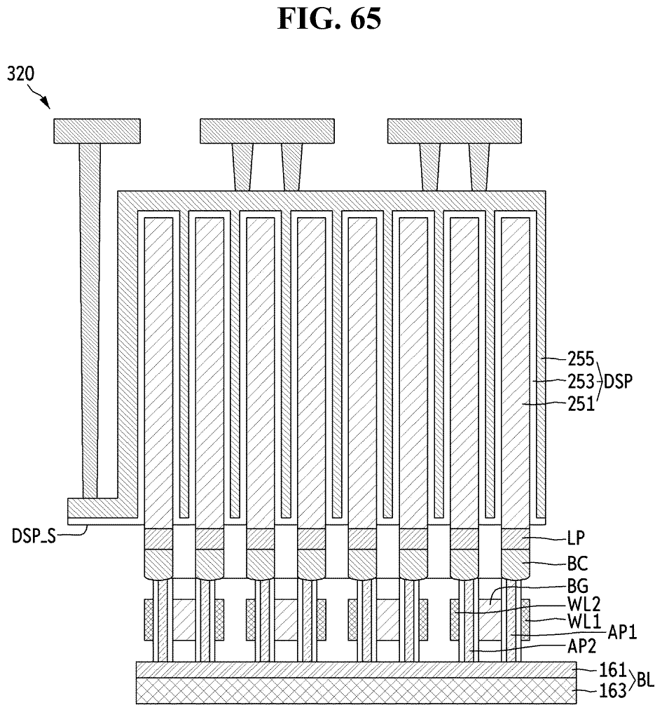

Referring to FIG. 62, the data storage pattern DSP may include a side area DSP_S. On the back surface of the data storage pattern DSP, the side area DSP_S thereof may be electrically connected to the second cell contact structure 320. Referring to FIG. 63, On the front surface of the data storage pattern DSP, the data storage pattern DSP may be electrically connected to the second cell contact structure 320. Referring to FIG. 64, on the front surface of the data storage pattern DSP, the side area DSP_S thereof may be electrically connected to the second cell contact structure 320. Referring to FIG. 65, on the front surface of the data storage pattern DSP, the side area DSP_S and a top area of the data storage pattern DSP may be electrically connected to the second cell contact structures 320, respectively.

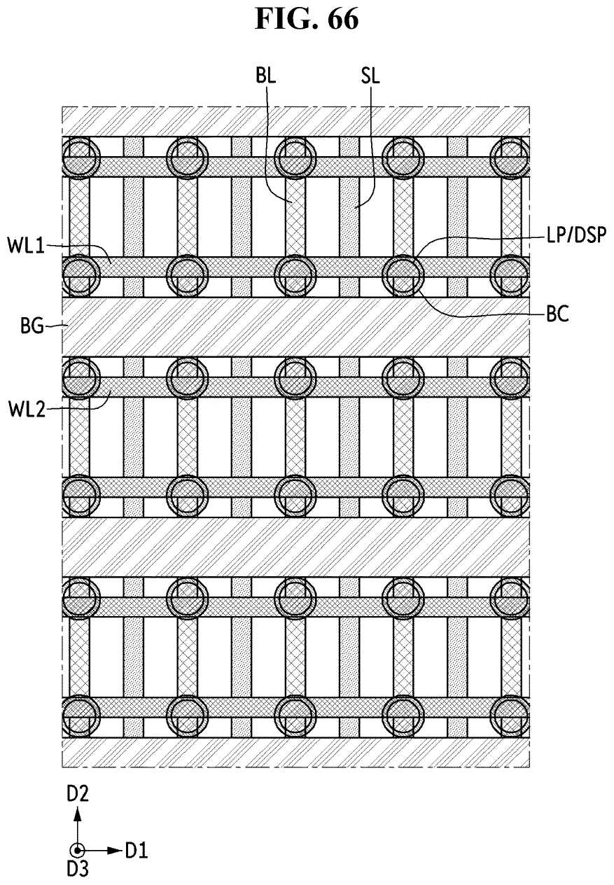

FIGS. 66 to 69 are diagrams for illustrating an arrangement relationship of the data storage pattern, the landing pattern, and the contact pattern according to some embodiments.

Referring to FIG. 66, the data storage patterns DSP may be arranged to be spaced from each other by an equal spacing in the first direction D1. The landing pads LP may be arranged to be spaced from each other by an equal spacing in the first direction D1. The contact patterns BC may be arranged to be spaced from each other by an equal spacing in the first direction D1. Alternatively, the data storage patterns DSP may be arranged to be spaced from each other by an equal spacing in the second direction D2. The landing pads LP may be arranged to be spaced from each other by an equal spacing in the second direction D2. The contact patterns BC may be arranged to be spaced from each other by an equal spacing in the second direction D2.

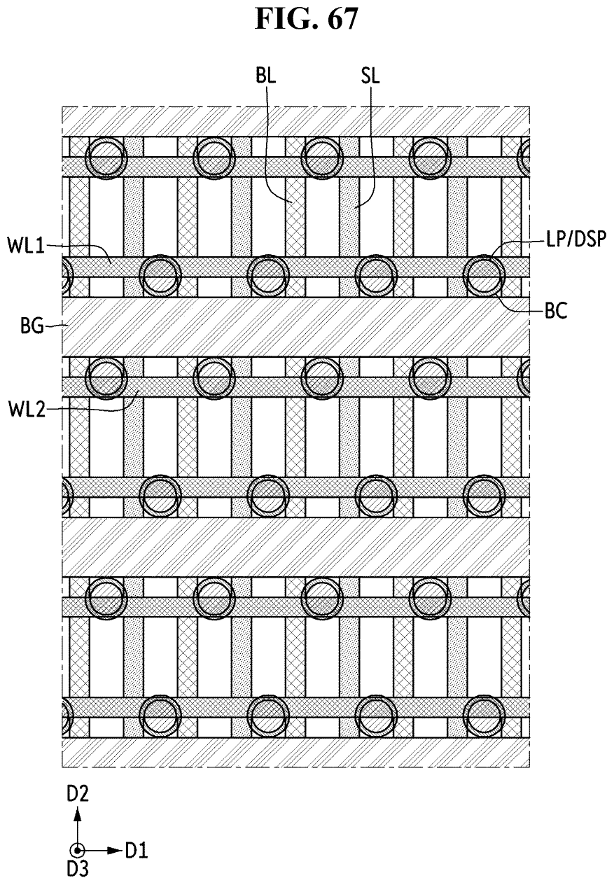

Referring to FIG. 67, in the plan view, the data storage patterns DSP may be arranged in the zigzag manner or in a honeycomb manner. The landing pads LP may be arranged in the zigzag manner or in a honeycomb manner. The contact patterns BC may be arranged in the zigzag manner or in a honeycomb manner.

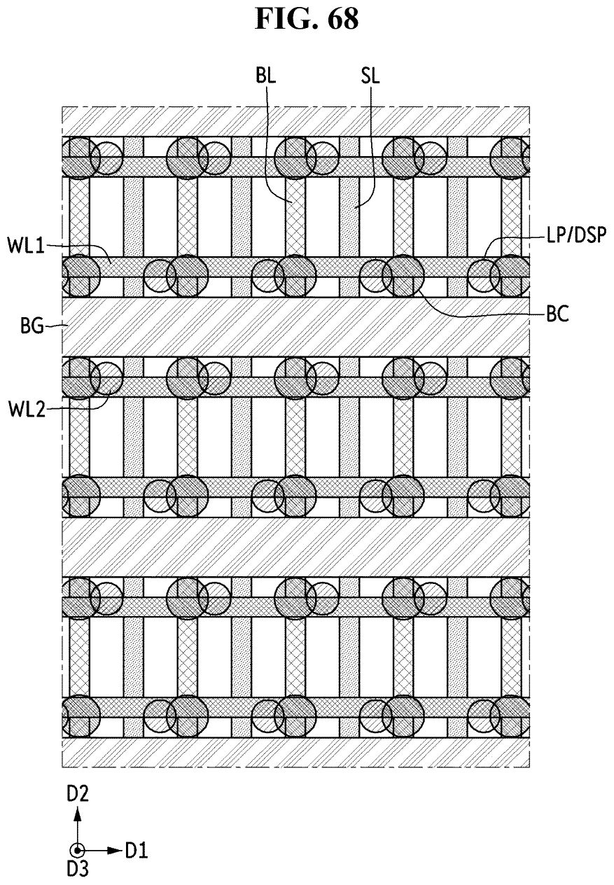

Referring to FIG. 68, the data storage pattern DSP may be misaligned with the contact pattern BC in the plan view. Each data storage pattern DSP may overlap a portion of each contact pattern BC.

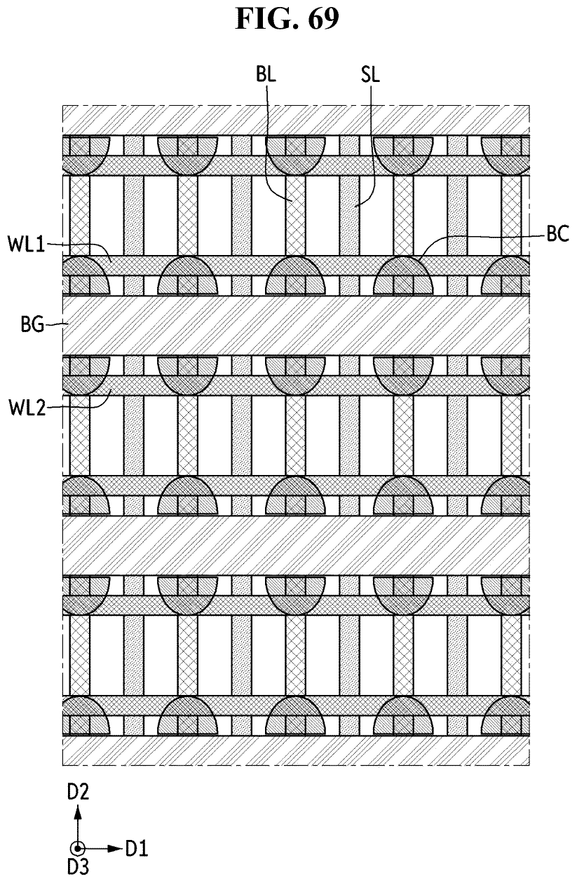

Referring to FIG. 69, the contact pattern BC may have a semicircular or semi-elliptic shape in a plan view. The contact patterns BC may be arranged symmetrically with each other around the back gate electrode BG disposed therebetween in a plan view.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor memory device comprising:
a peripheral circuit substrate;
a peripheral circuit element disposed on the peripheral circuit substrate;
a peripheral circuit contact structure disposed on the peripheral circuit substrate and connected to the peripheral circuit element;
a first bonding pad disposed on the peripheral circuit contact structure;
a second bonding pad disposed on the first bonding pad;
an active pattern disposed on the second bonding pad and including a first surface and a second surface opposite to each other in a first direction, and a first sidewall and a second sidewall opposite to each other in a second direction;
a data storage pattern disposed between the active pattern and the second bonding pad and connected to the first surface of the active pattern;
a bit-line disposed on the active pattern, connected to the second surface of the active pattern, and extending in the second direction;
a word-line disposed on the first sidewall of the active pattern and extending in a third direction;
a back gate electrode disposed on the second sidewall of the active pattern and extending in the third direction;
a first cell contact structure disposed between the second bonding pad and the data storage pattern so as to connect the second bonding pad and the data storage pattern to each other;
a first lower contact via connecting the first cell contact structure and the back gate electrode to each other; and
a second lower contact via connecting the first cell contact structure and the word-line to each other,
wherein a width of the first lower contact via decreases as the first lower contact via extends toward the back gate electrode, and
wherein a width of the second lower contact via decreases as the second lower contact via extends toward the word-line.

2. The semiconductor memory device of claim 1, further comprising:
a second cell contact structure disposed on the word-line and the back gate electrode;
a first upper contact via connecting the second cell contact structure and the back gate electrode to each other; and
a second upper contact via connecting the second cell contact structure and the word-line to each other,
wherein a width of the first upper contact via decreases as the first upper contact via extends toward the back gate electrode, and
wherein a width of the second upper contact via decreases as the second upper contact via extends toward the word-line.

3. The semiconductor memory device of claim 2, wherein a length in the first direction of the first upper contact via and a length in the first direction of the first lower contact via are different from each other, and
wherein a length in the first direction of the second upper contact via and a length in the first direction of the second lower contact via are different from each other.

4. The semiconductor memory device of claim 2, wherein a width in the second direction of the first lower contact via based on a lower surface of the back gate electrode and a width in the second direction of the first upper contact via based on an upper surface of the back gate electrode are different from each other.

5. The semiconductor memory device of claim 1, further comprising:
a landing pad disposed on the data storage pattern and connecting the data storage pattern and the active pattern to each other;
a contact landing pad spaced apart from the landing pad in the second direction; and
a third lower contact via connecting the contact landing pad and the first cell contact structure to each other,
wherein a width of the third lower contact via decreases as the third lower contact via extends toward the contact landing pad.

6. The semiconductor memory device of claim 5, further comprising:
a second cell contact structure disposed on the contact landing pad; and
a third upper contact via connecting the second cell contact structure and the contact landing pad to each other,
wherein a width of the third upper contact via decreases as the third upper contact via extends toward the contact landing pad.

7. The semiconductor memory device of claim 5, further comprising:
a fourth upper contact via connecting the contact landing pad and the bit-line to each other,
wherein a width of the fourth upper contact via decreases as the fourth upper contact via extends toward the contact landing pad.

8. The semiconductor memory device of claim 5, wherein, based on the second bonding pad, a vertical level of the word-line is higher than a vertical level of the contact landing pad.

9. The semiconductor memory device of claim 1, wherein the data storage pattern is disposed between the second bonding pad and the bit-line.

10. The semiconductor memory device of claim 9, wherein the data storage pattern includes a plate electrode, a storage electrode, and a capacitor dielectric film disposed between the plate electrode and the storage electrode, and
wherein a surface of the plate electrode as a lower surface of the data storage pattern faces an upper surface of the peripheral circuit substrate.

11. The semiconductor memory device of claim 1, wherein the active pattern includes first active patterns and second active patterns arranged alternately with each other along the second direction,
wherein the back gate electrode is disposed between the first and second active patterns and extends in the third direction,
wherein the word-line includes:
a first word-line disposed adjacent to the first active pattern and extending in the third direction; and
a second word-line disposed adjacent to the second active pattern and extending in the third direction,
wherein the first active pattern is disposed between the first word-line and the back gate electrode, and
wherein the second active pattern is disposed between the second word-line and the back gate electrode.

12. The semiconductor memory device of claim 11, further comprising:
a shielding conductive line disposed on the first active pattern and the second active pattern and adjacent to the bit-line,
wherein the shielding conductive line extends in the second direction.

13. A semiconductor memory device comprising:
a peripheral circuit substrate;
a peripheral circuit element disposed on the peripheral circuit substrate;
a peripheral circuit contact structure disposed on the peripheral circuit substrate and connected to the peripheral circuit element;
a first bonding pad disposed on the peripheral circuit contact structure;
a second bonding pad disposed on the first bonding pad;
a bit-line disposed on the second bonding pad, and including upper and lower surfaces opposite to each other in a first direction, wherein the bit-line extends in a second direction;
a first word-line disposed on the upper surface of the bit-line and extending in a third direction;
a second word-line disposed on the upper surface of the bit-line and extending in the third direction, the second word-line spaced apart from the first word-line in the second direction;
a back gate electrode disposed on the upper surface of the bit-line and between the first word-line and the second word-line, the back gate electrode extending in the third direction;
a first active pattern disposed between the first word-line and the back gate electrode and extending in the second direction;
a second active pattern disposed between the second word-line and the back gate electrode and extending in the second direction;
a data storage pattern disposed on the first and second active patterns and connected to the first active pattern and the second active pattern;
a first cell contact structure disposed on the lower surface of the bit-line so as to connect the bit-line and the second bonding pad to each other;
a first lower contact via connecting the first cell contact structure and the back gate electrode to each other; and
a second lower contact via connecting the first cell contact structure and the first word-line to each other,
wherein a width of the first lower contact via decreases as the first lower contact via extends toward the back gate electrode,
wherein a width of the second lower contact via decreases as the second lower contact via extends toward the first word-line.

14. The semiconductor memory device of claim 13, further comprising:
a second cell contact structure disposed on the data storage pattern;
a first upper contact via connecting the second cell contact structure and the back gate electrode to each other; and
a second upper contact via connecting the second cell contact structure and the first word-line to each other,
wherein a width of the first upper contact via decreases as the first upper contact via extends toward the back gate electrode, and
wherein a width of the second upper contact via decreases as the second upper contact via extends toward the first word-line.

15. The semiconductor memory device of claim 14, further comprising:
a landing pad disposed on the first and second active patterns so as to connect the first and second active patterns to the data storage pattern;
a contact landing pad spaced apart from the landing pad in the second direction;
a third lower contact via connecting the first cell contact structure and the contact landing pad to each other; and
a third upper contact via connecting the second cell contact structure and the contact landing pad to each other,
wherein a width of the third lower contact via decreases as the third lower contact via extends toward the contact landing pad, and
wherein a width of the third upper contact via decreases as the third upper contact via extends toward the contact landing pad.

16. The semiconductor memory device of claim 15, wherein the width of the first lower contact via based on a lower surface of the back gate electrode and the width of the second upper contact via based on an upper surface of the back gate electrode are different from each other.

17. A semiconductor memory device comprising:
a peripheral circuit substrate;
a peripheral circuit element disposed on the peripheral circuit substrate;
a peripheral circuit contact structure disposed on the peripheral circuit substrate and connected to the peripheral circuit element;
a first bonding pad disposed on the peripheral circuit contact structure;
a second bonding pad disposed on the first bonding pad;
an active pattern disposed on the second bonding pad and including a first surface and a second surface opposite to each other in a first direction, and a first sidewall and a second sidewall opposite to each other in a second direction;
a data storage pattern disposed between the active pattern and the second bonding pad and connected to the first surface of the active pattern;
a bit-line disposed on the active pattern, connected to the second surface of the active pattern, and extending in the second direction;
a word-line disposed on the first sidewall of the active pattern and extending in a third direction;
a back gate electrode disposed on the second sidewall of the active pattern and extending in the third direction;
a first cell contact structure disposed between the second bonding pad and the data storage pattern so as to connect the second bonding pad and the data storage pattern to each other;
a second cell contact structure disposed on the word-line or the back gate electrode;
a first lower contact via connecting the first cell contact structure and the back gate electrode to each other;
a first upper contact via connecting the second cell contact structure and the back gate electrode to each other;
a second lower contact via connecting the first cell contact structure and the word-line to each other; and
a second upper contact via connecting the second cell contact structure and the word-line to each other,
wherein each of a width of the first lower contact via and a width of the first upper contact via decreases as each of the first lower contact via and the first upper contact via extends toward the back gate electrode, and
wherein each of a width of the second lower contact via and a width of the second upper contact via decreases as each of the second lower contact via and the second upper contact via extends toward the word-line.

18. The semiconductor memory device of claim 17, further comprising:
a landing pad disposed on the data storage pattern so as to connect the data storage pattern and the active pattern to each other;
a contact landing pad spaced apart from the landing pad in the second direction;
a third lower contact via connecting the first cell contact structure and the contact landing pad to each other; and
a third upper contact via connecting the second cell contact structure and the contact landing pad to each other,
wherein each of a width of the third lower contact via and a width of the third upper contact via decreases as each of the third lower contact via and the third upper contact via extends toward the contact landing pad.

19. The semiconductor memory device of claim 18, further comprising:
a fourth upper contact via connecting the contact landing pad and the bit-line to each other,
wherein a width of the fourth upper contact via decreases as the fourth upper contact via extends toward the contact landing pad.

20. The semiconductor memory device of claim 17, wherein the data storage pattern includes a plate electrode, a storage electrode, and a capacitor dielectric film disposed between the plate electrode and the storage electrode, and
wherein a surface of the plate electrode as a lower surface of the data storage pattern faces an upper surface of the peripheral circuit substrate.
